(19) United States
(12) Patent Application Publication
(10) Pub. No.: US 2024/0363532 A1
(43) Pub. Date: Oct. 31, 2024

(54) INTEGRATED CIRCUIT INCLUDING BACKSIDE CONTACT AND METHOD OF DESIGNING THE INTEGRATED CIRCUIT

(71) Applicant: SAMSUNG ELECTRONICS CO., LTD., Suwon-si (KR)

(72) Inventors: Seungyoung Lee, Suwon-si (KR); Jungho Do, Suwon-si (KR)

(21) Appl. No.: 18/626,985

(22) Filed: Apr. 4, 2024

(30) Foreign Application Priority Data
Apr. 26, 2023 (KR) 10-2023-0054978
Sep. 19, 2023 (KR) 10-2023-0125003

(51) Int. Cl. H01L 23/528; H01L 23/522; H01L 27/092; H01L 29/06; H01L 29/417; H01L 29/423; H01L 29/66; H01L 29/775; H01L 29/786

(52) U.S. Cl. CPC H01L 23/5283; H01L 23/5226; H01L 27/092; H01L 29/0673; H01L 29/41733; H01L 29/42392; H01L 29/66439; H01L 29/775; H01L 29/78696

(57) ABSTRACT

An integrated circuit includes a standard cell including a first transistor and a second transistor each disposed on a front side of a substrate, a backside via passing through the substrate in a vertical direction with respect to the substrate, a backside wiring layer including a backside power rail disposed on a backside of the substrate and connected with a first source/drain of the first transistor through the backside via, and a backside contact extending in a first direction between the standard cell and the backside wiring layer and electrically connecting a second source/drain of the first transistor with a first source/drain of the second transistor, wherein a bottom level of the backside contact differs from a top level of the backside power rail, and the backside contact is electrically insulated from the backside power rail.

### CROSS-REFERENCE TO RELATED APPLICATIONS

This application claims priority under 35 U.S.C. § 119 to Korean Patent Application Nos. 10-2023-0054978, filed on Apr. 26, 2023, and 10-2023-0125003, filed on Sep. 19, 2023, in the Korean Intellectual Property Office, the disclosure of which are incorporated by reference herein in their entirety.

### TECHNICAL FIELD

The present disclosure relates to an integrated circuit, and more particularly, to an integrated circuit including a backside contact and a method of designing the integrated circuit.

### BACKGROUND

As demands for the degree of integration increase in the semiconductor industry advance, the widths, intervals, and/or heights of wirings included in an integrated circuit may decrease and adverse effects of a parasitic element of the wiring may increase. Also, a power supply voltage of integrated circuits may decrease to reduce power consumption and the operation speed, and due to this, the adverse effect of a parasitic element of a wiring on an integrated circuit may be more pronounced. Therefore, there is demand for a method of designing an integrated circuit for effectively routing wirings and vias while avoiding these adverse effects.

### SUMMARY

The present disclosure provides an integrated circuit and a method of designing the same, in which a power performance area (PPA) may be improved by using a backside contact or a backside wiring as a signal line.

In general, aspects of the subject matter described in this specification can be embodied in an integrated circuit including: a standard cell including a first transistor and a second transistor each disposed on a front side of a substrate, a backside via passing through the substrate in a vertical direction with respect to the substrate, a backside wiring layer including a backside power rail disposed on a backside of the substrate and connected with a first source/drain of the first transistor through the backside via, and a backside contact extending in a first direction between the standard cell and the backside wiring layer and electrically connecting a second source/drain of the first transistor with a first source/drain of the second transistor, wherein a bottom level of the backside contact differs from a top level of the backside power rail, and the backside contact is electrically insulated from the backside power rail.

Another general aspect can be embodied in an integrated circuit including: a standard cell including a first transistor and a second transistor each disposed on a front side of a substrate, a backside via passing through the substrate in a vertical direction with respect to the substrate, a backside wiring layer including a backside power rail disposed on a backside of the substrate and connected with a source of the first transistor through the backside via, and a backside contact disposed between the standard cell and the backside wiring layer to correspond to an output node of the standard cell and electrically connected with a drain of the second transistor, wherein a bottom level of the backside contact differs from a top level of the backside power rail, and the backside contact is electrically insulated from the backside power rail.

Another general aspect can be embodied in an integrated circuit including: a standard cell including a first transistor disposed on a front side of a substrate, a backside via passing through the substrate in a vertical direction with respect to the substrate, a backside wiring layer including a backside power rail disposed on a backside of the substrate and connected with a source of the first transistor through the backside via, a first backside gate contact connected with a gate of the first transistor to pass through the substrate in the vertical direction, and a first backside contact disposed to extend in a first direction between the standard cell and the backside wiring layer and connected with the gate of the first transistor through the first backside gate contact, wherein a bottom level of the first backside contact differs from a top level of the backside power rail, and the first backside contact is electrically insulated from the backside power rail.

In some implementations, the integrated circuit further includes a front wiring layer disposed above the front side of the substrate. The front wiring layer can include a first front wiring line electrically connected with a gate of the first transistor; and a second front wiring line electrically connected with a second source/drain of the second transistor. The first and second front wiring lines extend in the first direction and are arranged in one row in the first direction. In some implementations, the front wiring layer further includes a third front wiring line spaced apart from the first front wiring line or the second front wiring line in a second direction; and a fourth front wiring line apart from the third front wiring line in the second direction. The second direction can be perpendicular to the first direction.

In some implementations, the backside contact overlaps the first front wiring line at least partially along a vertical direction and overlaps the second front wiring line at least partially along the vertical direction.

In some implementations, the backside contact does not overlap the first front wiring line along a vertical direction and does not overlap the second front wiring line along the vertical direction.

In some implementations, the backside contact overlaps the backside power rail at least partially along a vertical direction.

In some implementations, the backside contact does not overlap the backside power rail along a vertical direction.

In some implementations, the backside contact includes: a first pattern connected to the second source/drain of the first transistor and extending in a second direction perpendicular to the first direction; a second pattern connected to the first source/drain of the second transistor and extending in the second direction; and a third pattern electrically connecting the first pattern to the second pattern and extending in the first direction.

In some implementations, the standard cell includes: a first active region extending in a first direction, and a second active region disposed apart from the first active region in a second direction perpendicular to the first direction to extend in the first direction; and the backside contact includes: a first pattern overlapping the first active region along a vertical direction and extending in the first direction, and a second pattern contacting the first pattern and extending in the second direction.

In some implementations, the backside contact further includes a third pattern contacting the second pattern, overlapping the second active region along the vertical direction, and extending in the first direction.

In some implementations, the first and second transistors are disposed in the first active region, the standard cell further includes a third transistor disposed in the second active region, the first pattern is connected to the drain of the second transistor, and the second pattern connects a drain of the third transistor to the drain of the second transistor.

In some implementations, the integrated circuit includes a front wiring layer disposed above the front side of the substrate. The front wiring layer can include: a first front wiring line extending in the first direction at an upper portion of the first active region; and a second front wiring line extending in the first direction at an upper portion of the second active region.

In some implementations, the front wiring layer further includes a third front wiring line extending in the first direction from the first front wiring line and the second front wiring line.

In some implementations, the first front wiring line is connected to a gate of the second transistor.

In some implementations, the standard cell further includes first and second active regions extending in the first direction and spaced apart from each other in a second direction perpendicular to the first direction, and the first backside contact is disposed between the first and second active regions.

In some implementations, the standard cell further includes first and second active regions extending in the first direction and spaced apart from each other in a second direction perpendicular to the first direction, and the first backside contact overlaps the first active region or the second active region at least partially along a vertical direction.

In some implementations, the standard cell further includes a second transistor, and the integrated circuit further includes: a second backside gate contact connected to a gate of the second transistor to pass through the substrate in the vertical direction; and a second backside contact extending in the first direction between the standard cell and the backside wiring layer and connected to the gate of the second transistor through the second backside gate contact, and the first and second backside contacts are arranged in one row in the first direction.

In some implementations, the standard cell further includes first and second active regions extending in the first direction and spaced apart from each other in a second direction perpendicular to the first direction. The integrated circuit can further include a front wiring layer disposed above the front side of the substrate. The front wiring layer can further include: a first front wiring line extending in the first direction at an upper portion of the first active region; a second front wiring line extending in the first direction at an upper portion of the second active region; and a third front wiring line extending in the first direction from the first front wiring line and the second front wiring line.

### BRIEF DESCRIPTION OF THE DRAWINGS

FIG. 1 illustrates an example of a layout of an integrated circuit.

FIG. 2 depicts a circuit diagram corresponding to the integrated circuit of FIG. 1.

FIG. 3A is a plan view illustrating an example of a front side of the integrated circuit of FIG. 1, and FIG. 3B is a plan view illustrating an example of a backside of the integrated circuit of FIG. 1.

FIG. 4A is an example of a cross-sectional view taken along line X1-X1′ of FIG. 1, and FIG. 4B is an example of a cross-sectional view taken along line X2-X2′ of FIG. 1.

FIG. 5 illustrates an example of a layout of an integrated circuit.

FIG. 6A is a plan view illustrating an example of a front side of the integrated circuit of FIG. 5, and FIG. 6B is a plan view illustrating an example of a backside of the integrated circuit of FIG. 5.

FIG. 7A is an example of a cross-sectional view taken along line X3-X3′ of FIG. 5, and FIG. 7B is an example of a cross-sectional view taken along line X4-X4′ of FIG. 5.

FIG. 8 illustrates an example of a layout of an integrated circuit.

FIG. 9A is an example of a cross-sectional view taken along line X5-X5′ of FIG. 8, and FIG. 9B is an example of a cross-sectional view taken along line X5a-X5a′ of FIG. 8.

FIG. 10A illustrates an example of a layout of an integrated circuit, and FIG. 10B is an example of a cross-sectional view taken along line X5b-X5b′ of FIG. 10A.

FIGS. 11A to 11C illustrate examples of layouts of an integrated circuit.

FIG. 12 illustrates an example of a layout of an integrated circuit.

FIG. 13A is an example of a cross-sectional view taken along line X6-X6′ of FIG. 12, FIG. 13B is an example of a cross-sectional view taken along line X7-X7′ of FIG. 12, and FIG. 13C is an example of a cross-sectional view taken along line Y1-Y1′ of FIG. 12.

FIG. 14 illustrates an example of a layout of an integrated circuit.

FIG. 15 illustrates an example of a layout of an integrated circuit.

FIG. 16 is an example of a cross-sectional view taken along line X8-X8′ of FIG. 15.

FIG. 17 illustrates an example of a layout of an integrated circuit.

FIG. 18 illustrates an example of a layout of an integrated circuit.

FIG. 19 is an example of a cross-sectional view taken along line X9-X9′ of FIG. 18.

FIG. 20 illustrates an example of a layout of an integrated circuit.

FIG. 21A is an example of a cross-sectional view taken along line X10-X10′ of FIG. 20, and FIG. 21B is an example of a cross-sectional view taken along line X11-X11′ of FIG. 20.

FIGS. 22A to 22D illustrate examples of a device.

FIG. 23 is a flowchart illustrating an example of a method of manufacturing an integrated circuit.

FIG. 24 is an example of a block diagram illustrating a system-on-chip.

FIG. 25 is an example of a block diagram illustrating a computing system including a memory storing a program.

Like reference numerals refer to like elements in the drawings, and their repeated descriptions are omitted.

Herein, an X-axis direction may be referred to as a first horizontal direction or a first direction, a Y-axis direction may be referred to as a second horizontal direction or a second direction, and a Z-axis direction may be referred to as a vertical direction. A plane consisting of an X axis and a Y axis may be referred to as a horizontal plane, an element arranged in a +Z-axis direction relatively to another element may be referred to as being on the other element, and an element arranged in a −Z-axis direction relatively to another element may be referred to as being under the other element.

### DETAILED DESCRIPTION

An integrated circuit may be designed by arranging a plurality of standard cells. A standard cell may be a unit of a layout included in an integrated circuit, and in some implementations, may be referred to as a cell. A standard cell may be designed to include a plurality of transistors, so as to perform a predefined function. Such a standard cell scheme may be a method that previously prepares standard cells and combines the standard cells to design a dedicated large-scale integrated circuit customized for the spec of a customer or a user. A standard cell may be previously designed and verified and may be registered in a standard cell library, and an integrated circuit may be designed by performing a logic design where standard cells are combined, placement, and routing by using computer aided design (CAD). In the design of an integrated circuit, lengths and routing complexity of wirings and/or vias may decrease, and thus, the performance of the integrated circuit may be further enhanced.

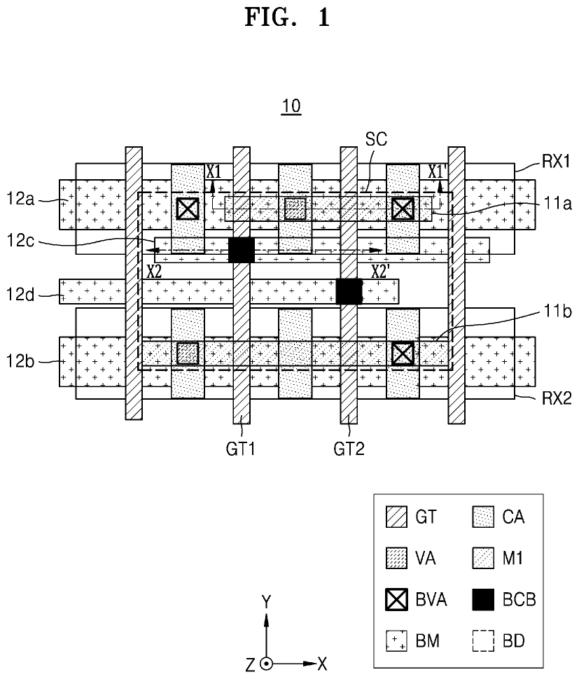

FIG. 1 illustrates an example of a layout of an integrated circuit 10.

Referring to FIG. 1, the integrated circuit 10 includes first and second active regions RX1 and RX2, gate lines GT, source/drain contacts CA, vias VA, a front wiring layer M1, a backside wiring layer BM, backside vias BVA, and backside gate contacts BCB. In some implementations, the integrated circuit 10 may be referred to as an integrated circuit device or a semiconductor device. For example, the gate lines GT, the source/drain contacts CA, and the backside gate contacts BCB may constitute a standard cell SC, and the standard cell SC may be defined by a cell boundary BD. The front wiring layer M1 may be arranged above the standard cell SC in a vertical direction Z, e.g., perpendicular to a horizontal plane parallel to XY plane. In the implementations illustrated herein, the phrase “source/drain contacts” may be understood to mean contacts to a source terminal region and/or contacts to a drain terminal region of a transistor. Additionally, the phrase “source/drain region” may be understood to mean a source terminal region and/or a drain terminal region of a transistor.

The integrated circuit 10 may include the front wiring layer M1 and the backside wiring layer BM and may implement a power distribution network (PDN) by using the front wiring layer M1 and the backside wiring layer BM. In this case, the front wiring layer M1 may be arranged above the standard cell SC in the vertical direction Z, and the backside wiring layer BM may be arranged below the standard cell SC in the vertical direction Z. Therefore, some of signals and/or power each applied to the integrated circuit 10 may be transferred through the front wiring layer M1, and the others may be transferred through the backside wiring layer BM. Accordingly, in some implementations, the complexity of routing may be considerably reduced compared to a structure where wirings are disposed only above a front side of a substrate, and a length of each wiring or each via may also be reduced, thereby enhancing the performance of the integrated circuit 10.

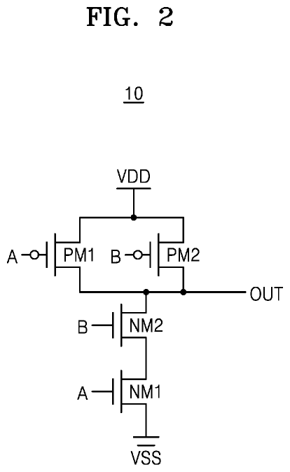

FIG. 2 is a circuit diagram corresponding to the integrated circuit 10 of FIG. 1.

Referring to FIG. 2 in conjunction with FIG. 1, the integrated circuit 10 includes P-type transistors PM1 and PM2 and N-type transistors NM1 and NM2. The P-type transistors PM1 and PM2 may be connected to each other in parallel, and the N-type transistors NM1 and NM2 may be serially connected to each other. As described above, the integrated circuit 10 may include a NAND gate cell, and the standard cell SC may correspond to the NAND gate cell.

The P-type transistor PM1 may include a source that receives a power supply voltage VDD, a gate that receives a first input signal A, and a drain connected with an output node OUT. The P-type transistor PM2 may include a source that receives the power supply voltage VDD, a gate which receives a second input signal B, and a drain connected with the output node OUT. The N-type transistor NM1 may include a source that receives a ground voltage VSS and a gate that receives the first input signal A. The N-type transistor NM2 may include a gate that receives the second input signal B and a drain connected with the output node OUT.

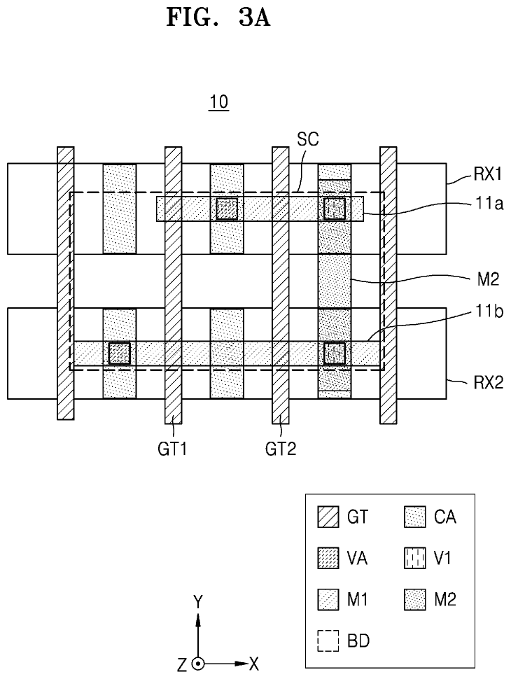

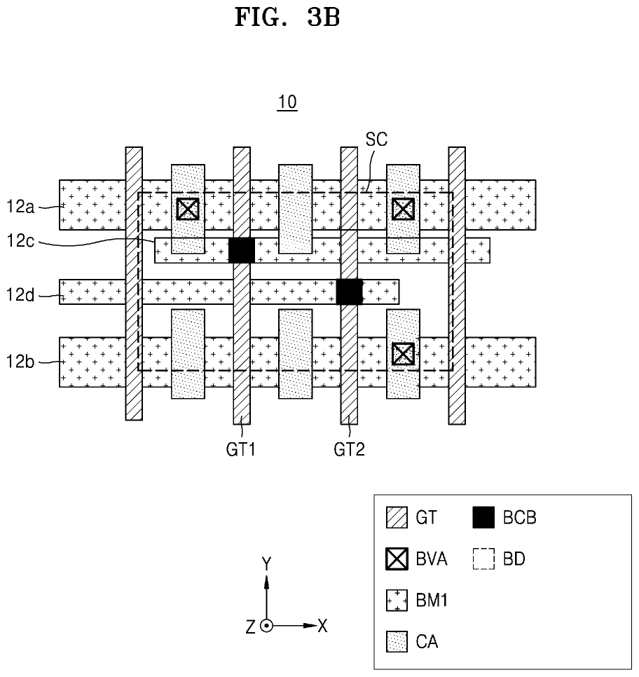

FIG. 3A is a plan view illustrating a front side of the integrated circuit 10 of FIG. 1.

Referring to FIGS. 1, 2, and 3A, the integrated circuit 10 is implemented as a semiconductor device, and a substrate where the semiconductor device is formed may include a first surface and a second surface. The first surface, for example, may be a surface where circuit devices such as a transistor are disposed, and herein, the first surface may be referred to as a front side. The second surface, for example, may be a surface opposite to the first surface, and herein, the second surface may be referred to as a backside.

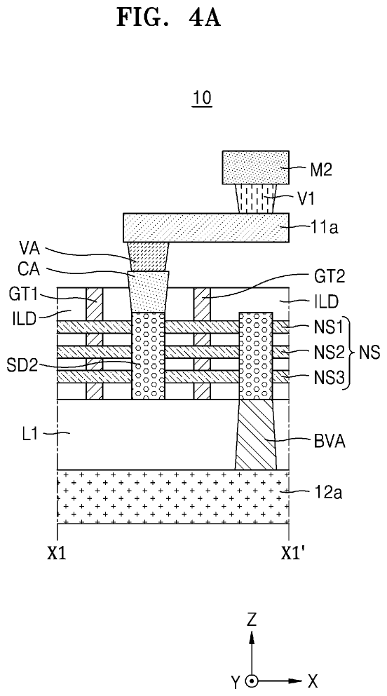

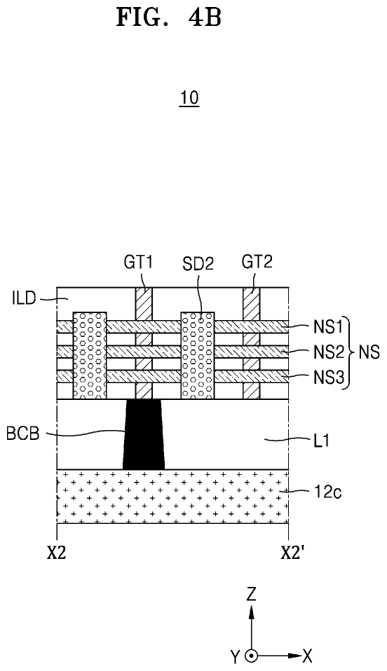

The first and second active regions RX1 and RX2 may each extend in a first direction X on the front side of a substrate and may be apart from each other in a second direction Y. For example, each of the first and second active regions RX1 and RX2 may be a diffusion region which is doped with impurities changing the electrical characteristics of a substrate material. For example, a length of each of the first and second active regions RX1 and RX2 in the second direction Y may correspond to a length of a nanosheet stack (for example, NS of FIG. 4A) in the second direction Y. In some implementations, the P-type transistors PM1 and PM2 may be disposed in the first active region RX1 and the N-type transistors NM1 and NM2 may be disposed in the second active region RX2. However, the inventive concept is not limited thereto, and in other examples, the N-type transistors NM1 and NM2 may be disposed in the first active region RX1 and the P-type transistors PM1 and PM2 may be disposed in the second active region RX2.

The gate lines GT may include first and second gate lines GT1 and GT2, which each extend in the second direction Y and are apart from each other in the first direction X. The gate lines GT may be defined as a conductive segment that includes a conductive material such as one or more metals or polysilicon. The source/drain contacts CA may be disposed on the first or second active region RX1 or RX2 and may each extend in the second direction Y.

The front wiring layers M1 and M2 may each be used as a signal wiring for transferring a signal for the integrated circuit 10, and the backside wiring layer BM may be used as a signal wiring for transferring power for the integrated circuit 10 and a signal wiring for transferring a signal for the integrated circuit 10. For example, the front wiring layers M1 and M2 may transfer an output signal for the standard cell SC. Also, for example, the backside wiring layer BM may supply the standard cell SC with power such as a positive supply voltage (for example, the power supply voltage VDD) and/or a negative supply voltage (for example, the ground voltage VSS), and moreover, may transfer an input signal for the standard cell SC.

In some implementations, the front wiring layer M1 may have a 2-track structure including 2-track signal lines above the standard cell SC. In detail, the front wiring layer M1 may include front wiring lines 11a and 11b, which each extend in the first direction X and are apart from each other in the second direction Y. For example, the front wiring line 11a may be disposed above the first active region RX1 and may be electrically connected with the source/drain contact CA through the via VA. For example, the front wiring line 11b may be disposed above the second active region RX2 and may be electrically connected with the source/drain contact CA through the via VA.

The front wiring layer M2 may be arranged above the front wiring layer M1 in the vertical direction Z. The front wiring layer M2 may extend in the second direction Y and may cross the first and second active regions RX1 and RX2. For example, the front wiring layer M2 may be connected to the front wiring lines 11a and 11b through the vias V1. The front wiring lines 11a and 11b and the front wiring layer M2 may correspond to an output terminal or the output node OUT of the standard cell SC.

FIG. 3B is a plan view illustrating the backside of the integrated circuit 10 of FIG. 1.

Referring to FIGS. 1, 2, and 3B, the gate lines GT and the source/drain contacts CA may be illustrated for describing positions of elements disposed on the backside of the integrated circuit 10. In some implementations, the backside wiring layer BM may have a 4-track structure including 2-track power rails and 2-track signal lines. In detail, the backside wiring layer BM may include first to fourth backside wiring lines 12a to 12d which each extend in the first direction X and are apart from one another in the second direction Y.

In some implementations, the first and second backside wiring lines 12a and 12b may be used as backside power rails, which supply a supply voltage to the standard cell SC. For example, the first backside wiring line 12a may be a first backside power rail that supplies a positive supply voltage (for example, the power supply voltage VDD), and the second backside wiring line 12b may be a second backside power rail that supplies a negative supply voltage (for example, the ground voltage VSS). The backside vias BVA may be respectively disposed on the first and second backside wiring lines 12a and 12b.

The first backside wiring line 12a may be connected to the source/drain region of the first active region RX1 through the backside via BVA, and for example, may provide the power supply voltage VDD to the source of the P-type transistor PM1 and the source of the P-type transistor PM2. The second backside wiring line 12b may be connected to the source/drain region of the second active region RX2 through the backside via BVA, and for example, may provide the ground voltage VSS to the source of the N-type transistor NM1.

The backside vias BVA may connect layers and elements, disposed on the backside, with the elements in the substrate (for example, the diffusion regions). In detail, the backside vias BVA may be connected to each of the source/drain regions of the first active region RX1 and the source/drain region of the second active region RX2. Therefore, the backside vias BVA may be referred to as a backside source/drain contact. As described above, a structure that connects a contact with a lower portion of an epitaxial region such as a source/drain region may be referred to as a direct backside contact (DBC). In some implementations, the DBC may include a backside contact and/or a backside via.

In some implementations, the third and fourth backside wiring lines 12c and 12d may be used as backside signal lines, which provide an input signal to the standard cell SC. For example, the third backside wiring line 12c may be a first backside signal line that provides the first input signal A, and the fourth backside wiring line 12d may be a second backside signal line that provides the second input signal B. The backside gate contacts BCB may be respectively disposed on the third and fourth backside wiring lines 12c and 12d.

The third backside wiring line 12c may be connected to the first gate line GT1 through the backside gate contact BCB, and for example, may provide the first input signal A to the gate of the P-type transistor PM1 and may provide the first input signal A to the gate of the N-type transistor NM1. The fourth backside wiring line 12d may be connected to the second gate line GT2 through the backside gate contact BCB, and for example, may provide the second input signal B to the gate of the P-type transistor PM2 and may provide the second input signal B to the gate of the N-type transistor NM2.

FIG. 4A is a cross-sectional view taken along line X1-X1′ of FIG. 1, and FIG. 4B is a cross-sectional view taken along line X2-X2′ of FIG. 1.

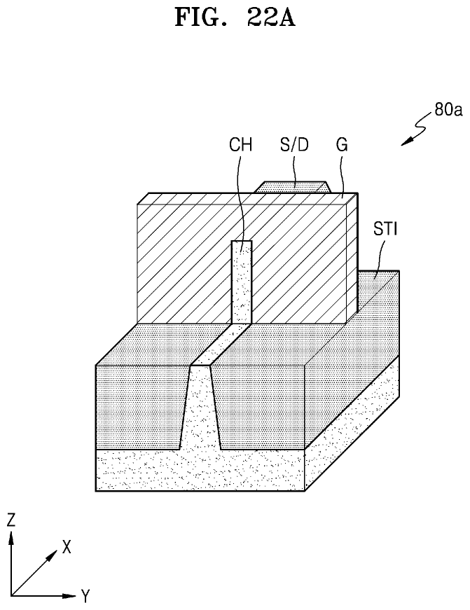

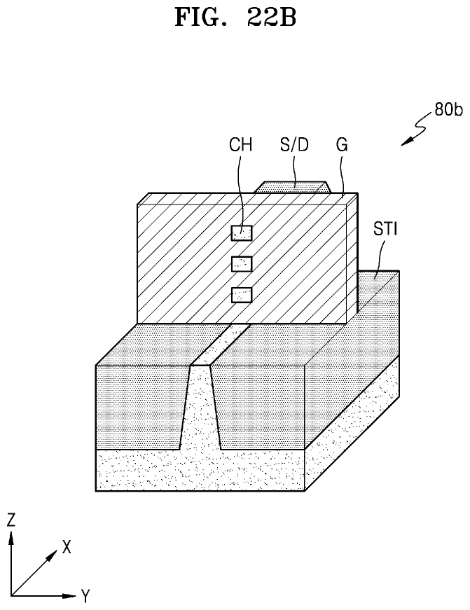

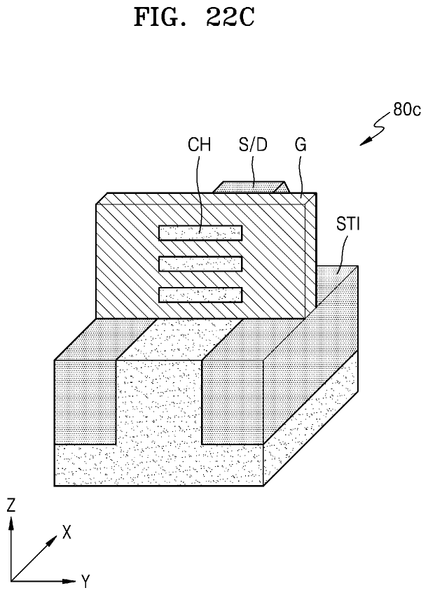

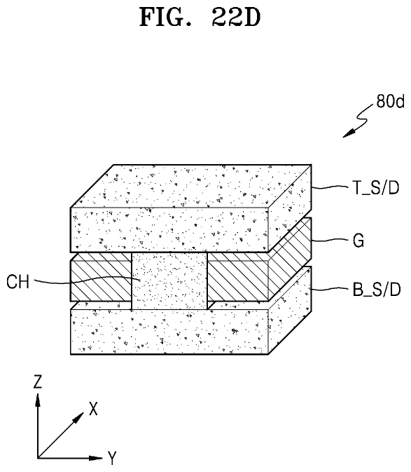

FIGS. 4A and 4B illustrate an example where a nanosheet is formed on an active region. For example, a plurality of nanosheets may be stacked on the active region, and a multi bridge channel (MBC) field effect transistor (FET) where a gate line surrounds the plurality of nanosheets may be formed on the active region. However, the integrated circuit 10 is not limited to the illustrations of FIGS. 4A and 4B. For example, a FinFET including a gate line and a fin formed on an active region may be formed. As another example, a gate-all-around (GAA) FET where a nanowire formed on an active region is surrounded by a gate line may be formed. As another example, a vertical GAA FET where a plurality of nanowires are vertically stacked on an active region and are surrounded by a gate line may be formed. This will be described below with reference to FIGS. 22A to 22D.

Referring to FIGS. 1 to 4B, a first layer L1 may include a substrate or a semiconductor substrate. In this case, an upper region of the first layer L1 may correspond to the first active region RX1. For example, the first layer L1 or the upper region of the first layer L1 may correspond to, for example, an N well formed in a P-type substrate. For example, the semiconductor substrate may include one of a silicon-on-insulator (SOI), silicon-on-sapphire, germanium, silicon-germanium, and gallium-arsenide. An interlayer insulation layer ILD may be disposed at an upper portion in a vertical direction Z with respect to the first layer L1. The interlayer insulation layer ILD may include an insulating material. For example, the insulating material may include one of oxide, nitride, and oxynitride.

In some implementations, the first layer L1 may correspond to a bulkless substrate. When performing a manufacturing process of the integrated circuit 10, gate lines, source/drain regions, contacts, vias, and/or a wiring layer may be formed on a front side of the substrate, and thus, a device wafer may be formed. Subsequently, the device wafer may be temporarily bonded to a carrier wafer, and by performing a back-grinding process on the device wafer, at least a portion of the substrate may be removed. As described above, a wafer on which a back-grinding process has been performed so that a height of a substrate is less than or equal to a reference height may be referred to as a bulkless wafer or a bulkless substrate.

A nanosheet stack NS extending in a first direction X may be disposed above the first layer L1. The nanosheet stack NS may include a plurality of nanosheets (for example, first to third nanosheets NS1 to NS3) overlapping one another in the vertical direction Z. For example, the nanosheet stack NS may be doped with N-type impurities, and may configure a P-type transistor. As another example, an N-type transistor may constitute the nanosheet stack NS, which may be doped with P-type impurities. In some implementations, the nanosheet stack NS may include silicon (Si), germanium (Ge), or SiGe. In some implementations, the nanosheet stack NS may include InGaAs, InAs, GaSb, InSb, or a combination thereof.

Each of the first and second gate lines GT1 and GT2 may cover the nanosheet stack NS and may surround each of the first to third nanosheets NS1 to NS3. Therefore, the first to third nanosheets NS1 to NS3 may have a GAA structure. A gate insulation layer may be disposed between each of the first and second gate lines GT1 and GT2 and the first to third nanosheets NS1 to NS3. The first and second source/drain regions SD1 and SD2 may include an epitaxial region of a semiconductor material such as silicon, boron, phosphorus, germanium, carbon, SiGe, and/or SiC.

The backside via BVA may be disposed on the first backside wiring line 12a, and moreover, may pass through the first layer L1 and may extend in the vertical direction Z. The backside via BVA may electrically connect the first backside wiring line 12a with the first source/drain region SD1. The backside gate contact BCB may be disposed on the third backside wiring line 12c, and moreover, may pass through the first layer L1 and may extend in the vertical direction Z. The backside gate contact BCB may electrically connect the third backside wiring line 12c with the first gate line GT1. The source/drain contact CA may be disposed on the second source/drain region SD1, and the via VA may be disposed on the source/drain contact CA. The front wiring line 11a may extend in the first direction X at an upper portion of the via VA. The via V1 may be disposed on the front wiring line 11a, and the front wiring layer M2 may extend in the second direction Y at an upper portion of the via V1.

For example, the first source/drain region SD1 may correspond to the source of the P-type transistor PM1, the second source/drain region SD2 may correspond to the drain of the P-type transistor PM1, and the second gate line GT2 may correspond to the gate of the P-type transistor PM1. In this case, the first backside wiring line 12a may provide the power supply voltage VDD to the source of the P-type transistor PM1 through the backside via BVA. The front wiring line 11a may be connected to the drain of the P-type transistor PM1 through the via VA and the source/drain contact CA.

As described above, in some implementations, the backside wiring layer BM may include the first to fourth backside wiring lines 12a to 12d, which each extend in the first direction X and are apart from one another in the second direction Y. In this case, the first to fourth backside wiring lines 12a to 12d may be disposed at the same level. In detail, top levels of the first to fourth backside wiring lines 12a to 12d may have heights equal to one another. Also, bottom levels of the first to fourth backside wiring lines 12a to 12d may have heights equal to one another.

However, the present disclosure is not limited thereto, and the first to fourth backside wiring lines 12a to 12d may be disposed at different levels. In detail, a bottom level of at least one of the first to fourth backside wiring lines 12a to 12d may differ from a top level of the other one of the first to fourth backside wiring lines 12a to 12d. For example, a bottom level of at least one of the first to fourth backside wiring lines 12a to 12d may be on a top level of the other one of the first to fourth backside wiring lines 12a to 12d in the vertical direction Z, and the at least one backside wiring line may be electrically insulated from the other one backside wiring line.

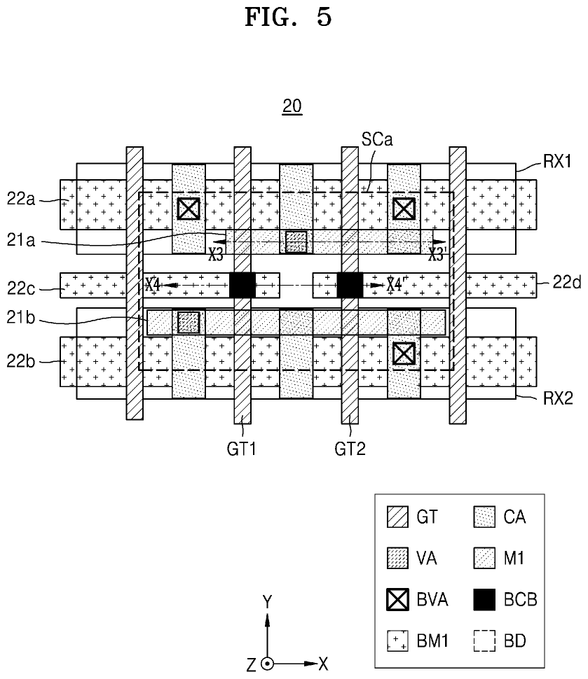

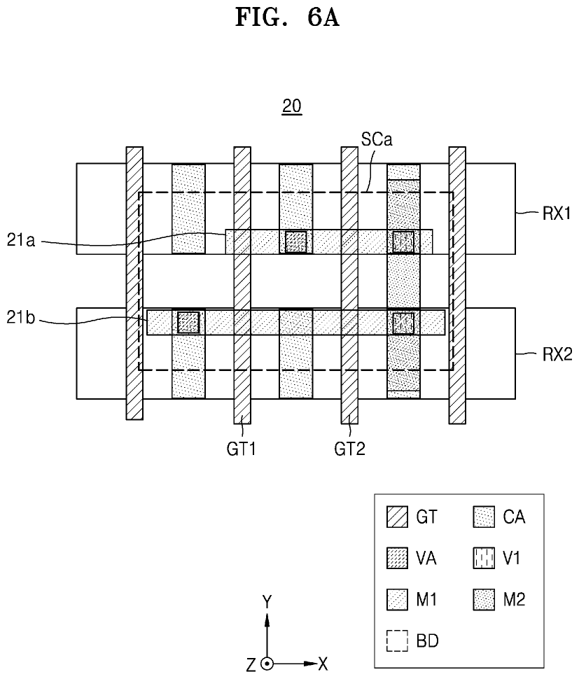

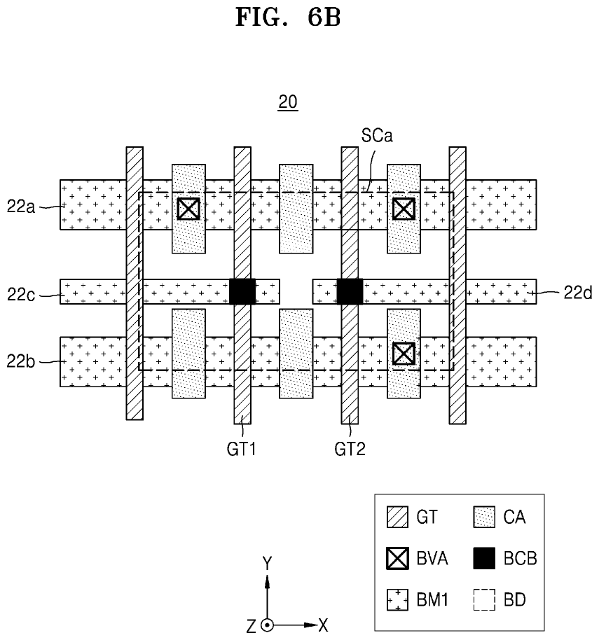

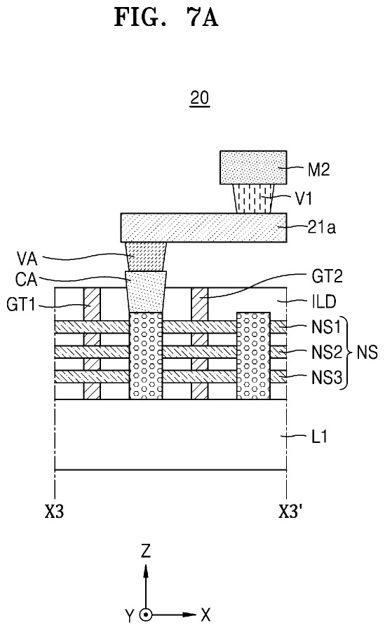

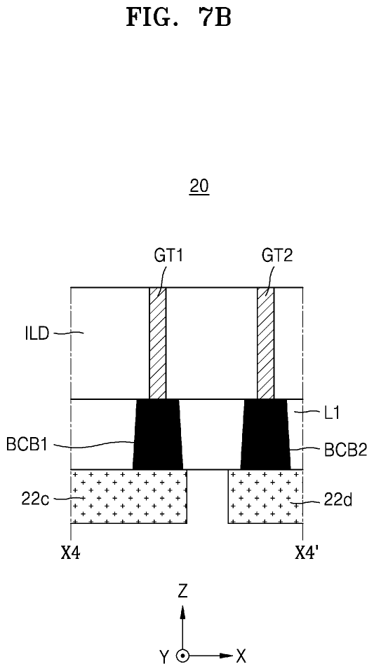

FIG. 5 illustrates a layout of an integrated circuit 20. FIG. 6A is a plan view illustrating a front side of the integrated circuit 20 of FIG. 5, and FIG. 6B is a plan view illustrating a backside of the integrated circuit 20 of FIG. 5. FIG. 7A is a cross-sectional view taken along line X3-X3′ of FIG. 5, and FIG. 7B is a cross-sectional view taken along line X4-X4′ of FIG. 5.

Referring to FIGS. 5 to 7B, the integrated circuit 20 includes first and second active regions RX1 and RX2, gate lines GT, source/drain contacts CA, vias VA, front wiring layers M1 and M2, a backside wiring layer BM, backside vias BVA, and backside gate contacts BCB. For example, the gate lines GT, the source/drain contacts CA, and the backside gate contacts BCB may constitute a standard cell SCa, and the standard cell SCa may be defined by a cell boundary BD. For example, the standard cell SCa may correspond to a configuration of the integrated circuit 10 of FIG. 2. The integrated circuit 20 may correspond to a modified version of the integrated circuit 10 of FIG. 1, and descriptions given above with reference to FIGS. 1 to 4B may be applied to other examples. Hereinafter, the difference between an example and the integrated circuit 10 illustrated in FIGS. 1 to 4B will be mainly described.

In some implementations, the front wiring layer M1 may have a 2-track structure including 2-track signal lines above the standard cell SCa. In detail, the front wiring layer M1 may include front wiring lines 21a and 21b, which each extend in a first direction X and are apart from each other in a second direction Y. For example, the front wiring line 21a may be disposed above a first active region RX1 and may be electrically connected with the source/drain contact CA through the via VA. For example, the front wiring line 21b may be disposed above a second active region RX2 and may be electrically connected with the source/drain contact CA through the via VA.

In some implementations, the backside wiring layer BM may have a 3-track structure including 2-track power rails and 1-track signal line. In detail, the backside wiring layer BM may include first to fourth backside wiring lines 22a to 22d, which each extend in the first direction X. The first and second backside wiring lines 22a and 22b may be used as backside power rails to supply a supply voltage to the standard cell SCa. For example, the first backside wiring line 22a may be a first backside power rail that supplies a positive supply voltage (for example, a power supply voltage VDD), and the second backside wiring line 22b may be a second backside power rail that supplies a negative supply voltage (for example, a ground voltage VSS). The backside vias BVA may be respectively disposed on the first and second backside wiring lines 22a and 22b.

The first backside wiring line 22a may be connected to source/drain regions of the first active region RX1 through the backside vias BVA, and for example, may provide the power supply voltage VDD to a source of the P-type transistor PM1 and a source of the P-type transistor PM2. The second backside wiring line 22b may be connected to a source/drain region of the second active region RX2 through the backside via BVA, and for example, may provide a ground voltage VSS to a source of the N-type transistor NM1. The backside vias BVA may be disposed on the first and second backside wiring lines 22a and 22b, and moreover, may pass through a first layer L1 and may extend in a vertical direction Z. The backside vias BVA may be connected to each of the source/drain regions of the first active region RX1 and the source/drain region of the second active region RX2.

The third and fourth backside wiring lines 22c and 22d may be used as backside signal lines, which provide an input signal to the standard cell SCa. The third and fourth backside wiring lines 22c and 22d may be apart from each other in the first direction X and may be arranged in one row in the first direction X. As described above, the third and fourth backside wiring lines 22c and 22d may occupy one track. For example, the third backside wiring line 22c may be a first backside signal line that provides a first input signal A, and the fourth backside wiring line 22d may be a second backside signal line that provides a second input signal B.

The third backside wiring line 22c may be connected to the first gate line GT1 through the backside gate contact BCB, and for example, may provide the first input signal A to a gate of the P-type transistor PM1 and may provide the first input signal A to a gate of the N-type transistor NM1. The fourth backside wiring line 22d may be connected to the second gate line GT2 through the backside gate contact BCB, and for example, may provide the second input signal B to a gate of the P-type transistor PM2 and may provide the second input signal B to a gate of the N-type transistor NM2.

The backside gate contact BCB1 may be disposed on the third backside wiring line 22c, and moreover, may pass through the first layer L1 and may extend in the vertical direction Z. Therefore, the backside gate contact BCB1 may electrically connect the third backside wiring line 22c to the first gate line GT1. The backside gate contact BCB2 may be disposed on the fourth backside wiring line 22d, and moreover, may pass through the first layer L1 and may extend in the vertical direction Z. Therefore, the backside gate contact BCB2 may electrically connect the fourth backside wiring line 22d to the second gate line GT2.

As described above, in some implementations, the backside wiring layer BM may include the first to fourth backside wiring lines 22a to 22d, which each extend in the first direction X. In this case, the first to fourth backside wiring lines 22a to 22d may be disposed at the same level. In detail, top levels of the first to fourth backside wiring lines 22a to 22d may have equal heights. Also, bottom levels of the first to fourth backside wiring lines 22a to 22d may have equal heights.

However, the present disclosure is not limited thereto, and the first to fourth backside wiring lines 22a to 22d may be disposed at different levels. In detail, a bottom level of at least one of the first to fourth backside wiring lines 22a to 22d may differ from a top level of the other one of the first to fourth backside wiring lines 22a to 22d. For example, a bottom level of at least one of the first to fourth backside wiring lines 22a to 22d may be on a top level of the other one of the first to fourth backside wiring lines 22a to 22d in the vertical direction Z, and the at least one backside wiring line may be electrically insulated from the other one backside wiring line.

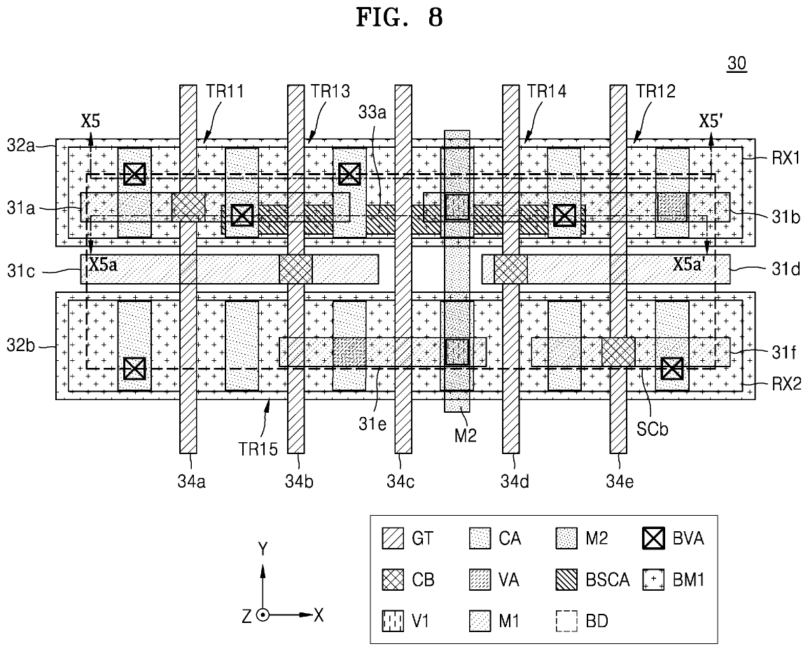

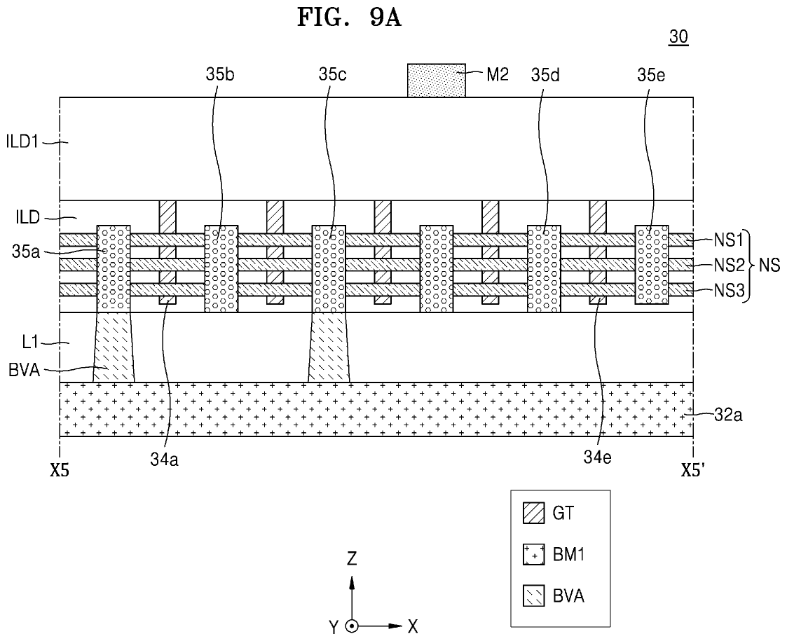

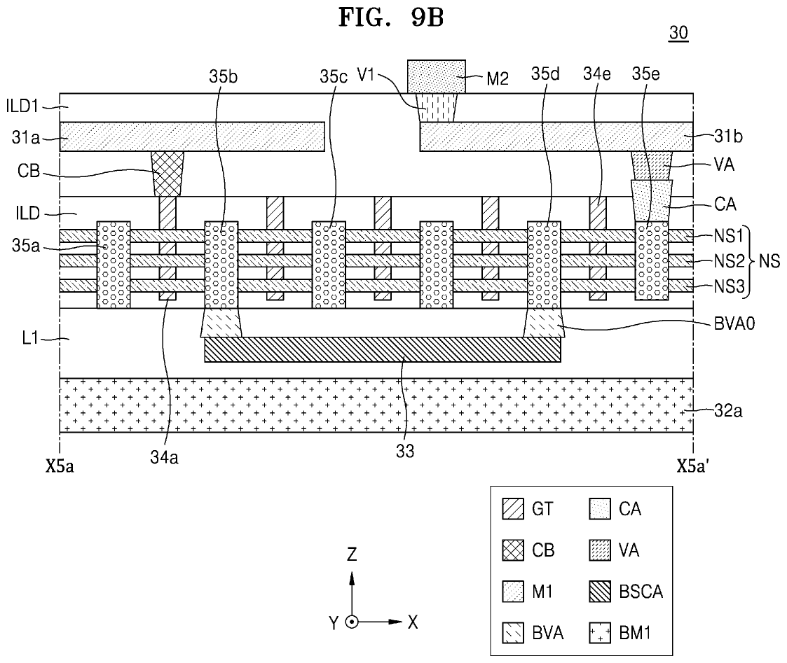

FIG. 8 illustrates a layout of an integrated circuit 30. FIG. 9A is a cross-sectional view taken along line X5-X5′ of FIG. 8, and FIG. 9B is a cross-sectional view taken along line X5a-X5a′ of FIG. 8.

Referring to FIGS. 8, 9A, and 9B, the integrated circuit 30 includes first and second active regions RX1 and RX2, gate lines GT, source/drain contacts CA, gate contacts CB, vias VA and V1, front wiring layers M1 and M2, a backside wiring layer BM, backside vias BVA, and a backside contact BSCA. In this case, the backside wiring layer BM and the backside contact BSCA may be disposed at different levels. In detail, a bottom level of the backside contact BSCA may differ from a top level of the backside wiring layer BM. For example, the gate lines GT, the source/drain contacts CA, and the gate contacts CB may constitute a standard cell SCb, and the standard cell SCb may be defined by a cell boundary BD. For example, the standard cell SCb may correspond to an AOI22 cell and may include a plurality of transistors including first to fifth transistors TR11 to TR15.

In some implementations, the front wiring layer M1 may have a 3-track structure including 3-track signal lines (for example, front wiring lines 31a to 31f) above the standard cell SCb. In some implementations, the backside wiring layer BM may have a 2-track structure including 2-track power rails (for example, first and second backside power rails 32a and 32b) below the standard cell SCb. In some implementations, the backside contact BSCA may include a backside contact 33 that extends in a first direction X, between the standard cell SCb and the backside wiring layer BM, and may correspond to a local interconnection of the standard cell SCb. In this case, the backside contact 33 may be electrically insulated from the first and second backside power rails 32a and 32b. For example, the gate lines GT may include gate lines 34a to 34c.

For example, the front wiring lines 31a and 31b may be disposed in an upper portion of the first active region RX1. In this case, the front wiring lines 31a and 31b may be arranged in one row in the first direction X and may thus occupy a first track. The front wiring line 31a may be electrically connected with the gate line 34a through the gate contact CB. For example, the front wiring line 31a may transfer a first input signal to the gate line 34a corresponding to a gate of the first transistor TR11. The front wiring line 31b may be electrically connected with a source/drain region 35d of the second transistor TR12 through the via VA. Also, the front wiring line 31b may be electrically connected with the front wiring layer M2 through the via V1. In this case, the front wiring layer M2 may correspond to an output node of the standard cell SCb.

For example, the front wiring lines 31c and 31d may be apart from each other in a second direction Y with respect to the front wiring lines 31a and 31b. In this case, the front wiring lines 31c and 31d may be arranged in one row in the first direction X and may thus occupy a second track. In some implementations, the front wiring lines 31c and 31d may be disposed in an upper portion of a dummy region between the first and second active regions RX1 and RX2. In some implementations, the front wiring lines 31c and 31d may at least partially overlap the first active region RX1 and/or the first backside power rail 32a. In some implementations, the front wiring lines 31c and 31d may at least partially overlap the second active region RX2 and/or the second backside power rail 32b. The front wiring line 31c may be electrically connected with the gate line 34b through the gate contact CB. For example, the front wiring line 31c may transfer a second input signal to the gate line 34b corresponding to a gate of the third transistor TR13. The front wiring line 31d may be electrically connected with the gate line 34d through the gate contact CB. For example, the front wiring line 31d may transfer a third input signal to the gate line 34d corresponding to a gate of the fourth transistor TR14.

For example, the front wiring lines 31e and 31f may be disposed in an upper portion of the second active region RX2. In this case, the front wiring lines 31e and 31f may be arranged in one row in the first direction X and may thus occupy a third track. The front wiring line 31e may be electrically connected with a source/drain contact CA of the second active region RX2 through the via VA. The front wiring line 31f may be electrically connected with the gate line 34e through the gate contact CB. For example, the front wiring line 31f may transfer a fourth input signal to the gate line 34e corresponding to a gate of the second transistor TR12.

For example, the first backside power rail 32a may overlap the first active region RX1 and may be electrically connected to the source/drain regions 35a and 35c of the first active region RX1 through the backside via BVA. For example, the second backside power rail 32b may overlap the second active region RX2 and may be electrically connected with the source/drain regions of the second active region RX2 through the backside vias BVA. For example, the backside contact 33 may overlap the first active region RX1 and may be electrically connected to the source/drain regions 35b and 35d of the first active region RX1 through a backside via BVA0.

For example, the source/drain region 35a may correspond to a source of the first transistor TR11, the source/drain region 35b may correspond to a drain of the first transistor TR11, and the gate line 34a may correspond to a gate of the first transistor TR11. In this case, the first backside power rail 32a may provide a power supply voltage VDD to the source of the first transistor TR11 through the backside via BVA. An interlayer insulation layer ILD may be disposed on a first layer L1, and an interlayer insulation layer ILD1 may be disposed on the interlayer insulation layer ILD.

For example, the source/drain region 35b may be electrically connected with the source/drain region 35d through the backside contact 33 and the backside via BVA0. In this case, the source/drain region 35d may correspond to a source of the second transistor TR12 and the source/drain region 35e may correspond to a drain of the second transistor TR12. The source/drain region 35e may be connected to the front wiring line 31b through the source/drain contact CA and the via VA. The front wiring line 31b may be connected to the front wiring layer M2 through the via V1. In this case, the front wiring layer M2 may correspond to an output node of the standard cell SCb.

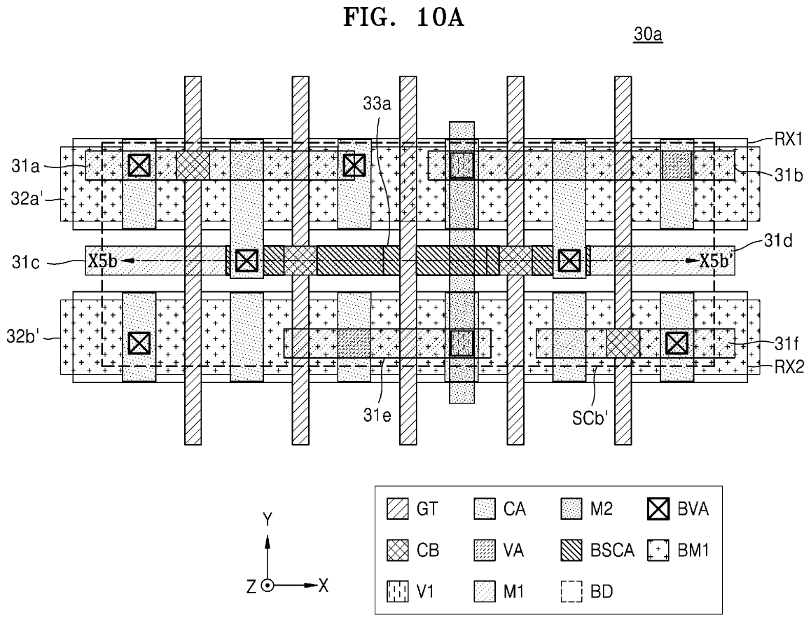

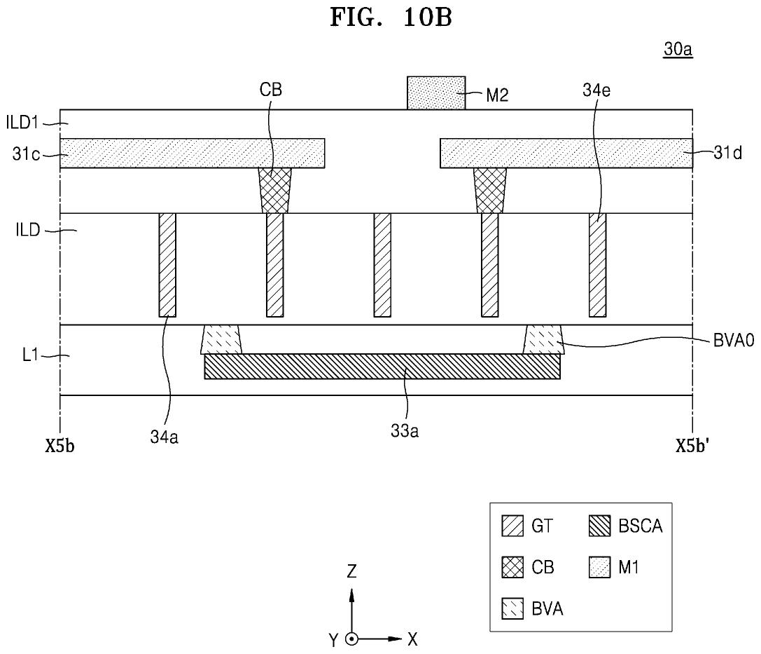

FIG. 10A illustrates a layout of an integrated circuit 30a. FIG. 10B is a cross-sectional view taken along line X5b-X5b′ of FIG. 10A.

Referring to FIGS. 10A and 10B, the integrated circuit 30a includes a standard cell SCb′ and may correspond to a modified version of the integrated circuit 30 of FIG. 8. In some implementations, a backside contact BSCA may include a backside contact 33a, and the backside contact 33a may not overlap first and second backside power rails 32a′ and 32b′. For example, a length of each of the first and second backside power rails 32a′ and 32b′ in a second direction Y may be shorter than a length of each of the first and second backside power rails 32a and 32b of FIG. 8 in the second direction Y. For example, the backside contact 33a may at least partially overlap front wiring lines 31c and 31d. For example, the backside contact 33a may not overlap a first active region RX1 and a second active region RX2. In this example, the backside contact 33a does not overlap either the first active region RX1 or the second active region RX2 along the Z axis (vertical direction) because the edges of the backside 33a is spaced apart from the edges of each of the first active region RX1 and the second active region RX2 in the Y direction (a horizontal direction).

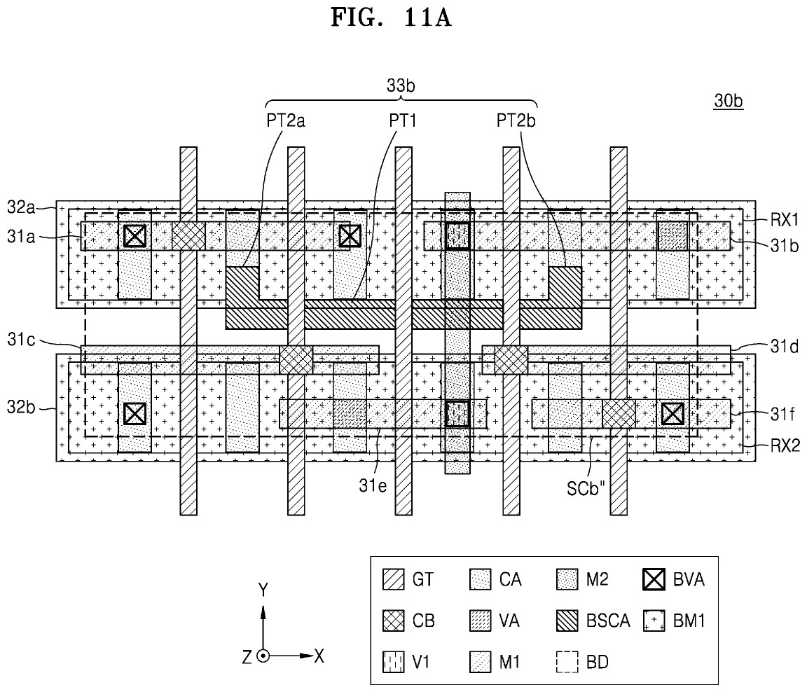

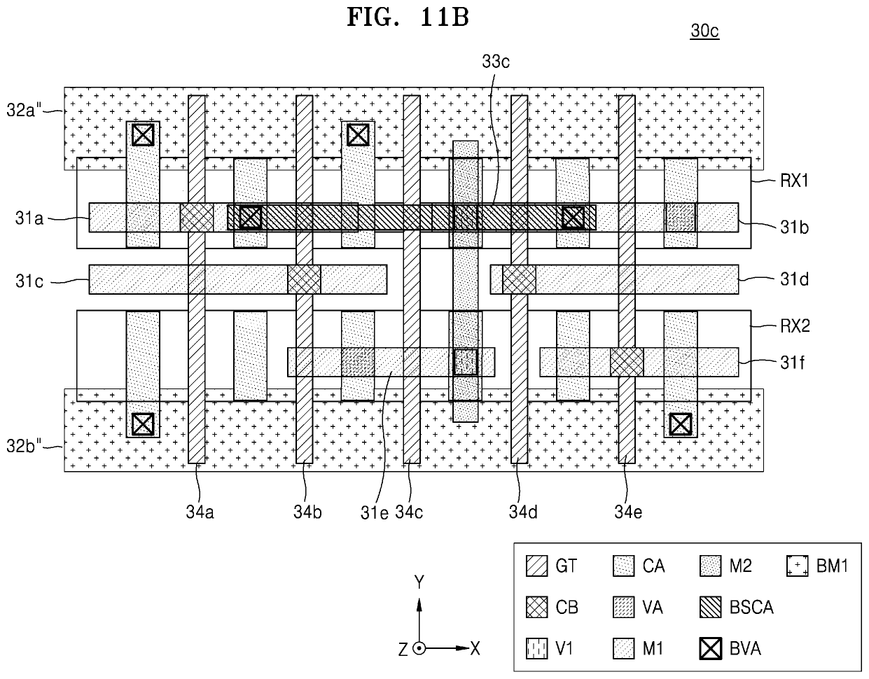

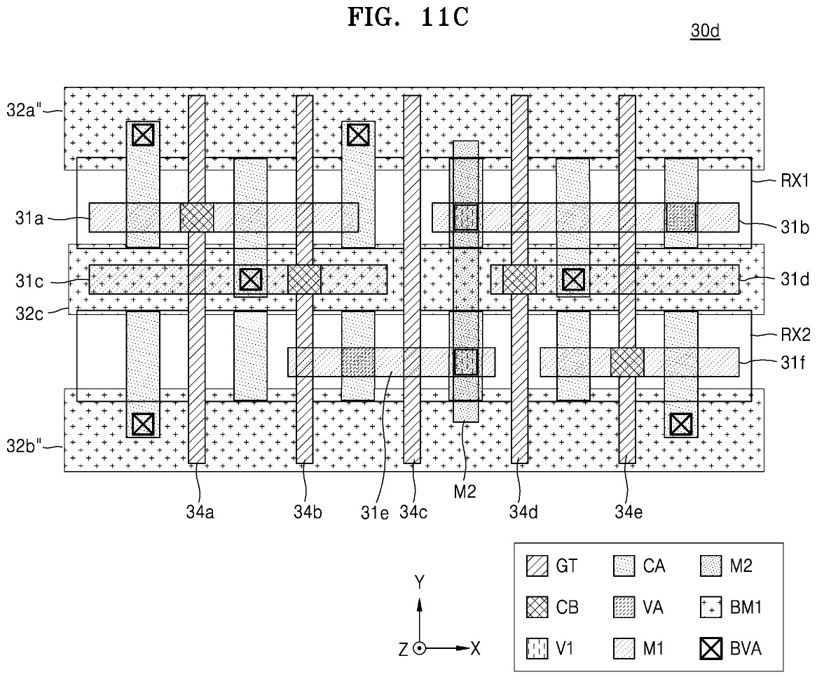

FIG. 11A illustrates a layout of an integrated circuit 30b.

Referring to FIG. 11A, the integrated circuit 30b may include a standard cell SCb″ and may correspond to a modified version of the integrated circuit 30 of FIG. 8. In some implementations, a backside contact BSCA may include a backside contact 33b, and the backside contact 33b may not overlap front wiring lines 31a and 31b. For example, the backside contact 33b may include patterns PT1, PT2a, and PT2b. The patterns PT2a and PT2b may each extend in a second direction Y, and the pattern PT1 may extend in a first direction X. The pattern PT1 may be connected to the patterns PT2a and PT2b. As described above, the backside contact 33b may include bidirectional patterns. For example, the pattern PT2a may be connected to a drain of a first transistor TR11, the pattern PT2b may be connected to a source of a second transistor TR12, and the pattern PT1 may connect the drain of the first transistor TR11 to the source of the second transistor TR12.

FIG. 11B illustrates a layout of an integrated circuit 30c.

Referring to FIG. 11B, the integrated circuit 30c includes first and second active regions RX1 and RX2, gate lines GT, source/drain contacts CA, gate contacts CB, vias VA and V1, front wiring layers M1 and M2, a backside wiring layer BM, backside vias BVA, and a backside contact BSCA. In this case, the backside wiring layer BM and the backside contact BSCA may be disposed at different levels. In detail, a bottom level of the backside contact BSCA may differ from a top level of the backside wiring layer BM. The integrated circuit 30c may correspond to a modified version of the integrated circuit 30 of FIG. 8.

The backside wiring layer BM may include first and second backside power rails 32a″ and 32b″, which each extend in a first direction X. For example, the first and second backside power rails 32a″ and 32b″ may be disposed at a boundary of a standard cell. For example, the first and second backside power rails 32a″ and 32b″ may at least partially overlap a cell boundary of the standard cell. For example, a length of each of the first and second backside power rails 32a″ and 32b″ in a second direction Y may be shorter than a length of each of the first and second backside power rails 32a and 32b of FIG. 8 in the second direction Y.

In some implementations, the backside contact BSCA may include a backside contact 33c that extends in a first direction X, and the backside contact 33c may correspond to a local interconnection. In this case, the backside contact 33c may be electrically insulated from the first and second backside power rails 32a″ and 32b″. For example, the backside contact 33c may at least partially overlap first and second front wiring lines 31a and 31b.

FIG. 11C illustrates a layout of an integrated circuit 30d.

Referring to FIG. 11C, the integrated circuit 30d includes first and second active regions RX1 and RX2, gate lines GT, source/drain contacts CA, gate contacts CB, vias VA and V1, front wiring layers M1 and M2, a backside wiring layer BM, and backside vias BVA. The integrated circuit 30d may correspond to a modified version of the integrated circuit 30c of FIG. 11B.

The backside wiring layer BM may include first and second backside power rails 32a″ and 32b″, which each extend in a first direction X and a backside wiring pattern 32c. In some implementations, the backside wiring pattern 32c may extend in the first direction X and may correspond to a local interconnection. In this case, the backside wiring pattern 32c may be connected to source/drain regions of the first active region RX1 through the backside via BVA. For example, the backside wiring pattern 32c may at least partially overlap third and fourth front wiring lines 31c and 31d.

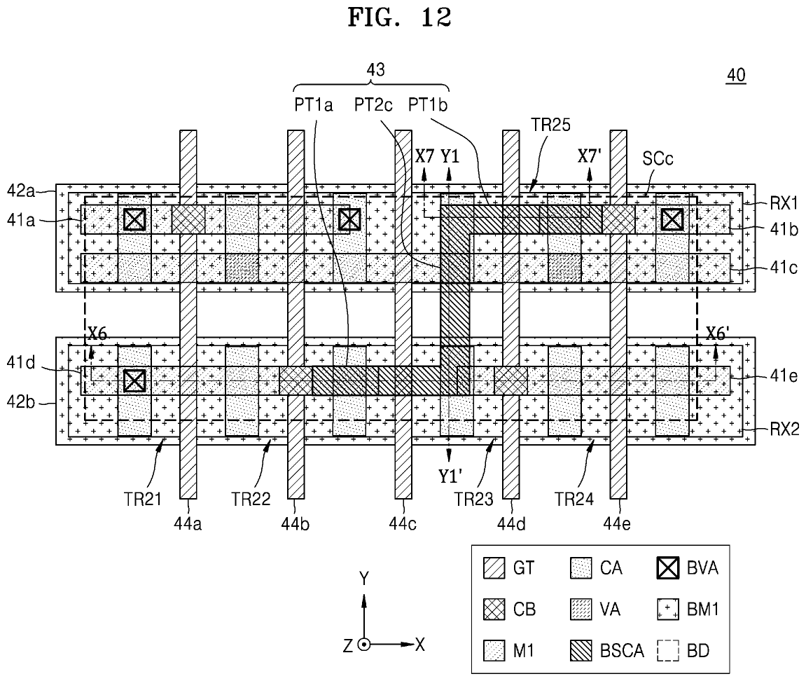

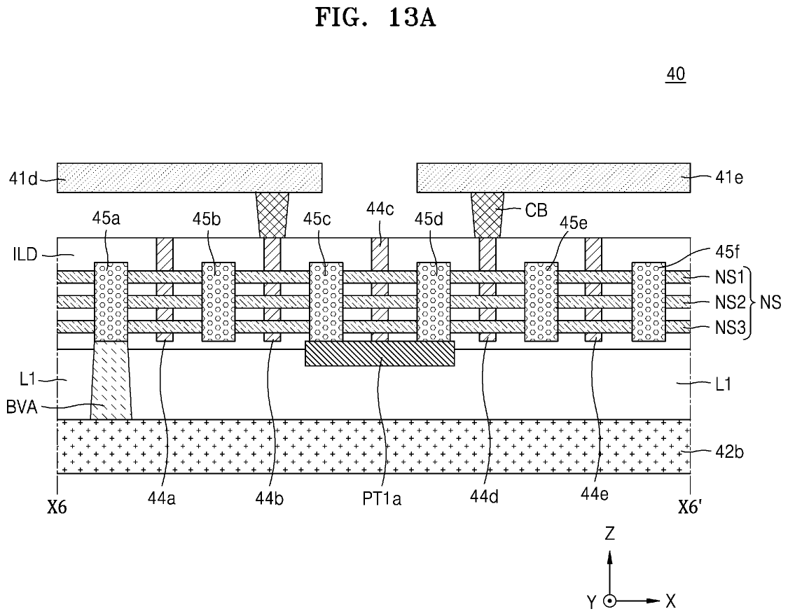

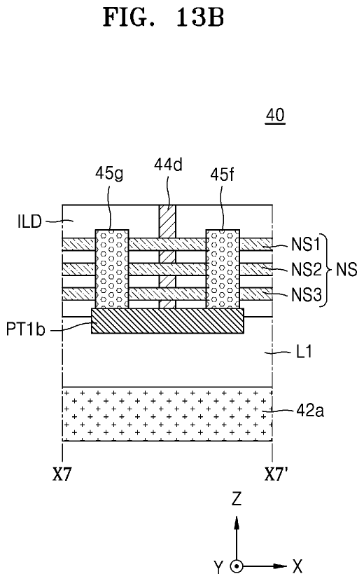

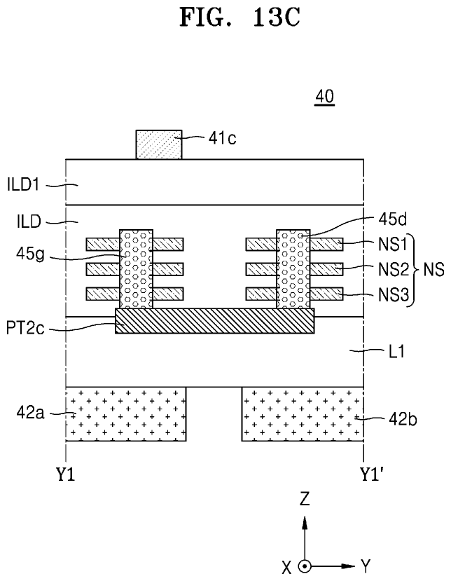

FIG. 12 illustrates a layout of an integrated circuit 40. FIG. 13A is a cross-sectional view taken along line X6-X6′ of FIG. 12, FIG. 13B is a cross-sectional view taken along line X7-X7′ of FIG. 12, and FIG. 13C is a cross-sectional view taken along line Y1-Y1′ of FIG. 12.

Referring to FIGS. 12 to 13B, the integrated circuit 40 included first and second active regions RX1 and RX2, gate lines GT, source/drain contacts CA, gate contacts CB, vias VA, front wiring layers M1 and M2, a backside wiring layer BM, backside vias BVA, and a backside contact BSCA. In this case, the backside wiring layer BM and the backside contact BSCA may be disposed at different levels. In detail, a bottom level of the backside contact BSCA may differ from a top level of the backside wiring layer BM. For example, the gate lines GT, the source/drain contacts CA, and the gate contacts CB may constitute a standard cell SCc, and the standard cell SCc may be defined by a cell boundary BD. For example, the standard cell SCc may correspond to an AO122 cell and may include a plurality of transistors including first to fifth transistors TR21 to TR25.

In some implementations, the front wiring layer M1 may have a 3-track structure including 3-track signal lines (for example, front wiring lines 41a to 41c) on the standard cell SCc. In some implementations, the backside wiring layer BM may have a 2-track structure including 2-track power rails (for example, first and second backside power rails 42a and 42b) on the standard cell SCc. In some implementations, the backside contact BSCA may include a backside contact 43 that is implemented in both directions between the standard cell SCc and the backside wiring layer BM, and the backside contact 43 may correspond to an output node of the standard cell SCc. In this case, the backside contact 43 may be electrically insulated from the first and second backside power rails 42a and 42b. For example, the gate lines GT may include gate lines 44a to 44c.

For example, the front wiring lines 41a and 41b may be disposed in an upper portion of the first active region RX1. In this case, the front wiring lines 41a and 41b may be arranged in one row in a first direction X and may thus occupy a first track. The front wiring line 41a may be electrically connected with the gate line 44a through the gate contact CB. For example, the front wiring line 41a may transfer a first input signal to the gate line 44a corresponding to a gate of the first transistor TR21. The front wiring line 41b may be electrically connected with the gate line 44c through the gate contact CB. For example, the front wiring line 41b may transfer a fourth input signal to the gate line 44c corresponding to a gate of the fourth transistor TR24.

For example, the front wiring line 41c may be apart from the front wiring lines 41a and 41b in a second direction Y and may occupy a second track. In some implementations, the front wiring line 41c may at least partially overlap the first active region RX1 and/or the first backside power rail 42a. In some implementations, the front wiring line 41c may not overlap the first active region RX1 and/or the first backside power rail 42a. The front wiring line 41c may be electrically connected with source/drain contacts CA of the first active region RX1 through the vias VA. For example, the front wiring line 41c may correspond to a local interconnection. In this case, an interlayer insulation layer ILD1 may be further disposed between the front wiring line 41c and the interlayer insulation layer ILD.

For example, the front wiring lines 41d and 41e may be disposed in an upper portion of the second active region RX2. In this case, the front wiring lines 41d and 41e may be arranged in one row in the first direction X and may thus occupy a third track. The front wiring line 41d may be electrically connected with the gate line 44b through the gate contact CB. For example, the front wiring line 41d may transfer a second input signal to the gate line 44b corresponding to a gate of the second transistor TR22. The front wiring line 41e may be electrically connected with the gate line 44d through the gate contact CB. For example, the front wiring line 41e may transfer a third input signal to the gate line 44d corresponding to a gate of the third transistor TR23.

For example, the first backside power rail 42a may overlap the first active region RX1 and may be electrically connected to the source/drain regions of the first active region RX1 through the backside vias BVA. For example, the second backside power rail 42b may overlap the second active region RX2 and may be electrically connected with the source/drain regions of the second active region RX2 through the backside vias BVA.

For example, the backside contact 43 may include patterns PT1a and PT1b extending in the first direction X and a pattern PT2c extending in the second direction Y. The pattern PT2c may cross the first and second active regions RX1 and RX2 and may be connected to the patterns PT1a and PT1b. The pattern PT1a may be connected to a source/drain region 45c of the second transistor TR22 and a source/drain region 45d of the third transistor TR23. The pattern PT2c may be connected to the source/drain region 45d of the third transistor TR23 and a source/drain region 45g of the fifth transistor TR25. The pattern PT1b may be connected to the source/drain region 45g of the fifth transistor TR25 and a source/drain region 45f of the fifth transistor TR25. In some implementations, the backside via BVA may be disposed between the backside contact 43 and the source/drain regions 45c, 45d, 45g, and 45f.

In FIG. 13A, for example, the source/drain region 45a may correspond to a source of the first transistor TR21, the source/drain region 45b may correspond to a drain of the first transistor TR21, and the gate line 44a may correspond to a gate of the first transistor TR21. In this case, the second backside power rail 42b may provide a ground voltage VSS to a source of the first transistor TR21 through the backside via BVA. In this case, the gate line 44b may correspond to a gate of the second transistor TR22 and the source/drain region 45c may correspond to a drain of the second transistor TR22. For example, the gate line 44d may correspond to a gate of the third transistor TR23, and the gate line 44d may be connected to the front wiring line 41e through the gate contact CB. The source/drain regions 45c and 45d may be electrically connected to each other through the pattern PT1a of the backside contact 43. In some implementations, the backside via BVA may be disposed between the source/drain regions 45c and 45d and the pattern PT1a of the backside contact 43. The backside contact 43 may correspond to an output node of the standard cell SCb.

In FIG. 13B, for example, the gate line 44d may correspond to a gate of the fifth transistor TR25, the source/drain region 45g may correspond to a drain of the fifth transistor TR25, and the source/drain region 45f may correspond to a source of the fifth transistor TR25. The source/drain regions 45g and 45f may be electrically connected with each other through a pattern PT1b of the backside contact 43. In some implementations, the backside via BVA may be disposed between the source/drain regions 45g and 45f and a pattern PT1a of the backside contact 43. The backside contact 43 may correspond to an output node of the standard cell SCb.

In FIG. 13C, for example, the source/drain region 45g may correspond to a drain of the fifth transistor TR25, and the source/drain region 45d may correspond to a drain of the third transistor TR23. The source/drain regions 45d and 45g may be electrically connected to each other through a pattern PT2c of the backside contact 43. In some implementations, the backside via BVA may be disposed between the source/drain regions 45d and 45g and the pattern PT1a of the backside contact 43. The backside contact 43 may correspond to an output node of the standard cell SCb.

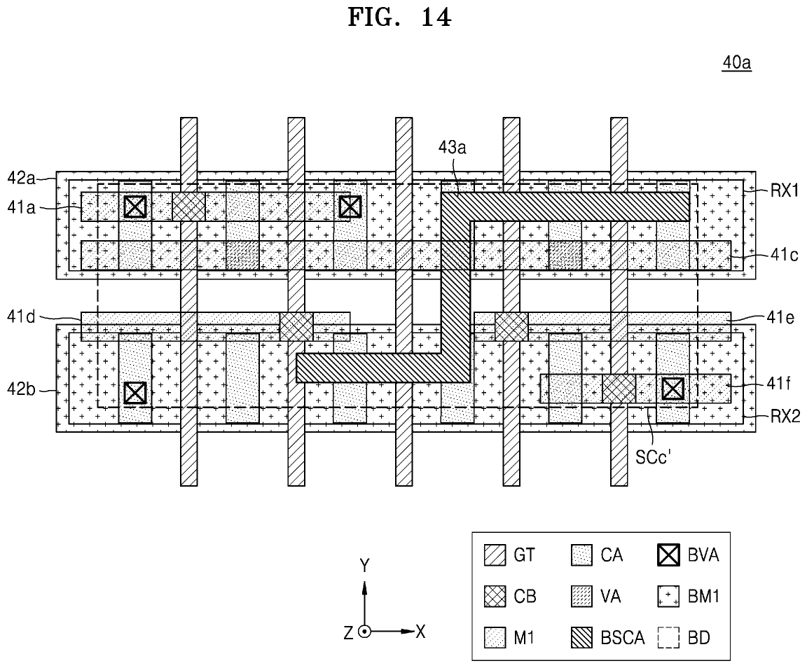

FIG. 14 illustrates a layout of an integrated circuit 40a.

Referring to FIG. 14, the integrated circuit 40a includes a standard cell SCc′ and may correspond to a modified version of the integrated circuit 40 of FIG. 12. In some implementations, a front wiring layer M1 may have a 4-track structure including 4-track signal lines (for example, front wiring lines 41a and 41c to 41f) on the standard cell SCc′. For example, the front wiring line 41a may occupy a first track, the front wiring line 41c may occupy a second track, the front wiring lines 41d and 41e may be arranged in one row in a first direction X and may occupy a third track, and the front wiring line 41f may occupy a fourth track. In some implementations, a backside contact BSCA may include a backside contact 43a.

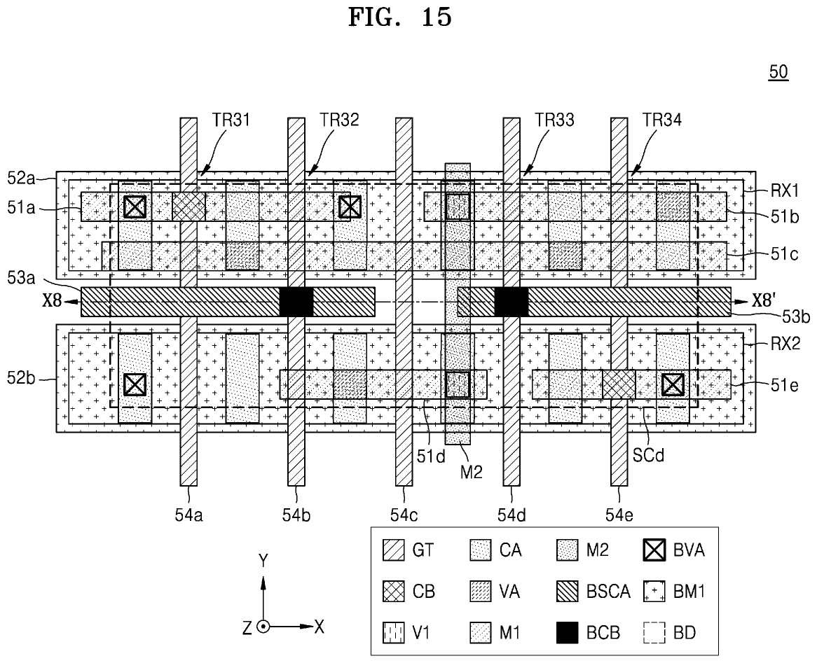

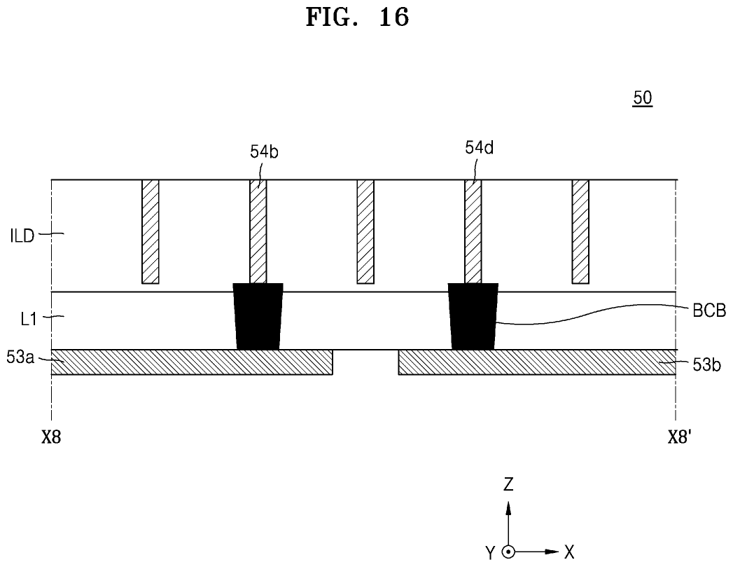

FIG. 15 illustrates a layout of an integrated circuit 50. FIG. 16 is a cross-sectional view taken along line X8-X8′ of FIG. 15.

Referring to FIGS. 15 and 16, the integrated circuit 50 includes first and second active regions RX1 and RX2, gate lines GT, source/drain contacts CA, gate contacts CB, vias VA and V1, front wiring layers M1 and M2, a backside wiring layer BM, backside vias BVA, backside gate contacts BCB, and a backside contact BSCA. In this case, the backside wiring layer BM and the backside contact BSCA may be disposed at different levels. In detail, a bottom level of the backside contact BSCA may differ from a top level of the backside wiring layer BM. For example, the gate lines GT, the source/drain contacts CA, the gate contacts CB, and the backside gate contacts BCB may constitute a standard cell SCd, and the standard cell SCd may be defined by a cell boundary BD. For example, the standard cell SCd may correspond to an AOI22 cell and may include a plurality of transistors including first to fifth transistors TR31 to TR34.

In some implementations, the front wiring layer M1 may have a 3-track structure including 3-track signal lines (for example, front wiring lines 51a to 51e) on the standard cell SCd. In some implementations, the backside wiring layer BM may have a 2-track structure including 2-track power rails (for example, first and second backside power rails 52a and 52b) on the standard cell SCd. In some implementations, the backside contact BSCA may include backside contacts 53a and 53b, which are arranged in one row in a first direction X between the standard cell SCd and the backside wiring layer BM and may correspond to input nodes of the standard cell SCd of the backside contacts 53a and 53d. In this case, the backside contacts 53a and 53b may be electrically insulated from the first and second backside power rails 52a and 52b. For example, the gate lines GT may include gate lines 54a to 54c.

For example, the front wiring lines 51a and 51b may be disposed in an upper portion of the first active region RX1. In this case, the front wiring lines 51a and 51b may be arranged in one row in the first direction X and may thus occupy a first track. The front wiring line 51a may be electrically connected with the gate line 54a through the gate contact CB and may transfer a first input signal to the gate line 54a corresponding to a gate of the first transistor TR31. The front wiring line 51b may be connected to a source/drain region of the fourth transistor TR34 through the via VA and may be connected to the front wiring layer M2 through the via V1.

For example, the front wiring line 51c may occupy a second track. In some implementations, the front wiring line 51c may at least partially overlap the first active region RX1 and/or the first backside power rail 52a. In some implementations, the front wiring line 51c may not overlap the first active region RX1 and/or the first backside power rail 52a. The front wiring line 51c may be electrically connected to source/drain contacts CA of the first active region RX1 through the vias VA. For example, the front wiring line 51c may correspond to a local interconnection, which connects a drain of the first transistor TR31 with a source of the fourth transistor TR34.

For example, the backside contacts 53a and 53b may be arranged in one row in the first direction X. The backside contact 53a may be electrically connected to the gate line 54b through the backside gate contact BCB and may transfer a second input signal to the gate line 54b corresponding to a gate of the second transistor TR32. The backside contact 53b may be electrically connected with the gate line 54d through the backside gate contact BCB and may transfer a third input signal to the gate line 54d corresponding to a gate of the third transistor TR33.

For example, the front wiring lines 51d and 51e may be disposed in an upper portion of the second active region RX2. In this case, the front wiring lines 51d and 51e may be arranged in one row in the first direction X and may thus occupy a third track. The front wiring line 51d may be connected to a source/drain region of the fifth transistor TR35 through the via VA and may be connected to the front wiring layer M2 through the via V1. The front wiring line 51e may transfer a fourth input signal to the gate line 54c corresponding to a gate of the fourth transistor TR34 through the gate contact CB.

For example, the first backside power rail 52a may overlap the first active region RX1 and may be electrically connected to the source/drain regions of the first active region RX1 through the backside vias BVA. For example, the second backside power rail 52b may overlap the second active region RX2 and may be electrically connected to the source/drain regions of the second active region RX2 through the backside vias BVA.

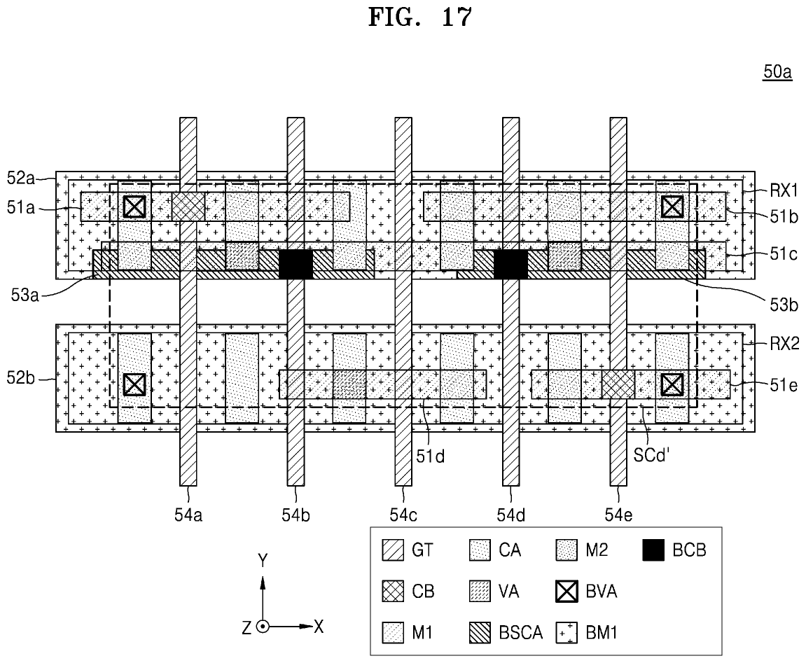

FIG. 17 illustrates a layout of an integrated circuit 50a.

Referring to FIG. 17, the integrated circuit 50a includes a standard cell SCd′ and may correspond to a modified version of the integrated circuit 50 of FIG. 15. In some implementations, backside contacts 53a and 53b may at least partially overlap a front wiring line 51c, a first active region RX1, and/or a first power rail 52a. However, the present disclosure is not limited thereto, and in other examples, the backside contacts 53a and 53b may at least partially overlap a second active region RX2 and/or a second power rail 52b.

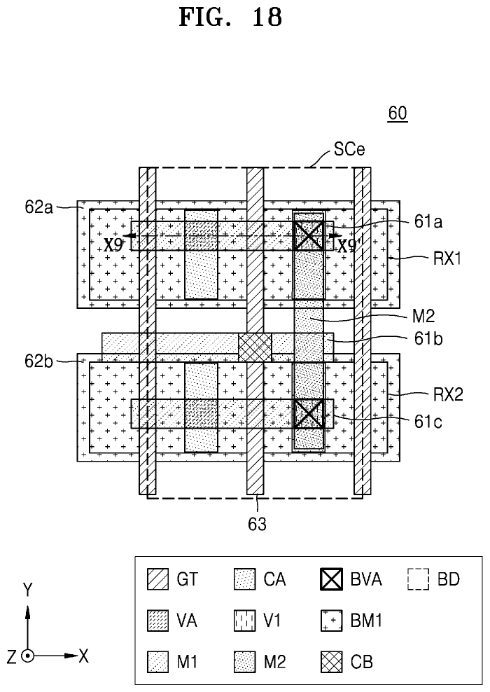

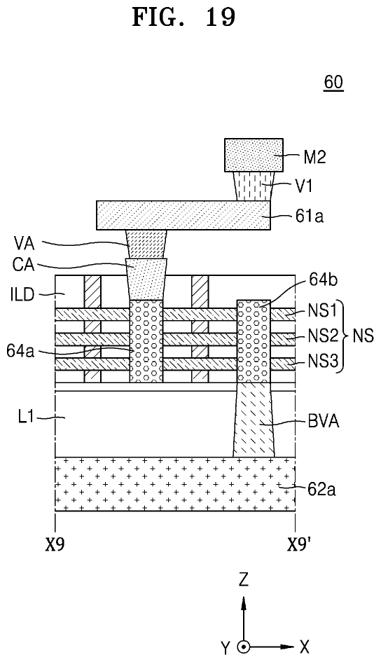

FIG. 18 illustrates a layout of an integrated circuit 60. FIG. 19 is a cross-sectional view taken along line X9-X9′ of FIG. 18.

Referring to FIGS. 18 and 19, the integrated circuit 60 includes first and second active regions RX1 and RX2, gate lines GT, source/drain contacts CA, a gate contact CB, vias VA and V1, front wiring layers M1 and M2, a backside wiring layer BM, and backside vias BVA. For example, the gate lines GT, the source/drain contacts CA, and the gate contacts CB may constitute a standard cell SCe, and the standard cell SCe may be defined by a cell boundary BD. For example, the standard cell SCe may correspond to an inverter cell.

In some implementations, the front wiring layer M1 may have a 3-track structure including 3-track signal lines (for example, front wiring lines 61a to 61c) on the standard cell SCe. In some implementations, the backside wiring layer BM may have a 2-track structure including 2-track power rails (for example, first and second backside power rails 62a and 62b) on the standard cell SCe. For example, the gate lines GT may include a gate line 63.

For example, the front wiring line 61a may be disposed in an upper portion of the first active region RX1 and may occupy a first track. The front wiring line 61a may be connected to a source/drain region 64a of the first active region RX1 through the via VA and the source/drain contact CA and may be connected to the front wiring layer M2 through the via V1. For example, the front wiring line 61c may be disposed in an upper portion of the second active region RX2 and may occupy a third track. The front wiring line 61c may be connected to a source/drain region of the second active region RX2 through the via VA and the source/drain contact CA and may be connected to the front wiring layer M2 through the via V1. As described above, the front wiring layer M2 may correspond to an output node of the standard cell SCe.

For example, the front wiring line 61b may be disposed between the front wiring lines 61a and 61c and may occupy a second track. The front wiring line 61b may be connected to the gate line 63 through the gate contact CB and may transfer an input signal to the gate line 63. As described above, the front wiring layer 61b may correspond to an input node of the standard cell SCc.

For example, the first backside power rail 62a may overlap the first active region RX1 and may be electrically connected to the source/drain regions of the first active region RX1 through the backside via BVA. For example, the second backside power rail 62b may overlap the second active region RX2 and may be electrically connected to the source/drain regions of the second active region RX2 through the backside via BVA.

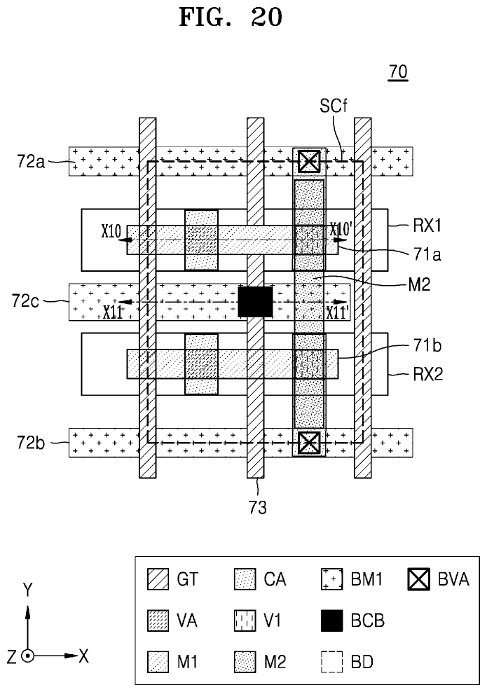

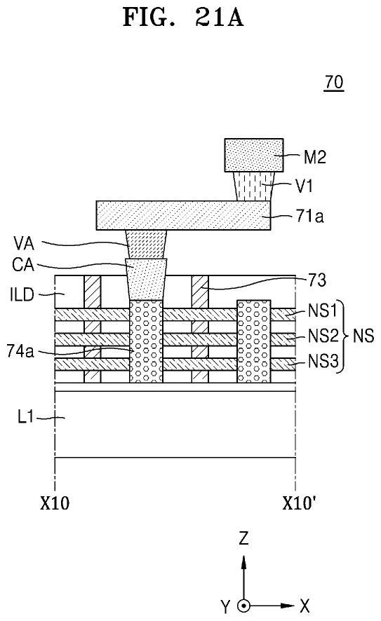

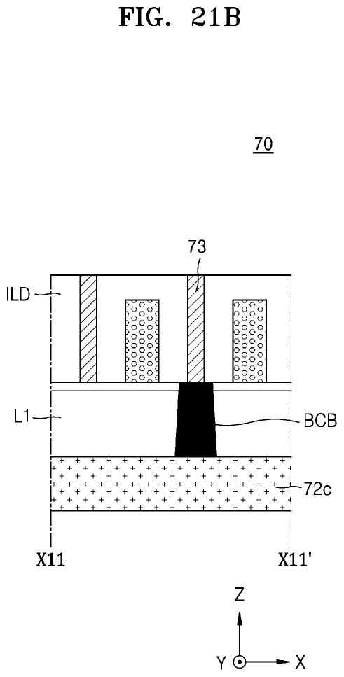

FIG. 20 illustrates a layout of an integrated circuit 70. FIG. 21A is a cross-sectional view taken along line X10-X10′ of FIG. 20, and FIG. 21B is a cross-sectional view taken along line X11-X11′ of FIG. 20.

Referring to FIGS. 20, 21A, and 21B, the integrated circuit 70 includes first and second active regions RX1 and RX2, gate lines GT, source/drain contacts CA, vias VA and V1, front wiring layers M1 and M2, a backside wiring layer BM, a backside gate contact BCA, and backside vias BVA. For example, the gate lines GT, the source/drain contacts CA, and the backside gate contact BCB may constitute a standard cell SCf, and the standard cell SCf may be defined by a cell boundary BD. For example, the standard cell SCf may correspond to an inverter cell.

In some implementations, the front wiring layer M1 may have a 2-track structure including 2-track signal lines (for example, front wiring lines 71a and 71b) on the standard cell SCf. In some implementations, the backside wiring layer BM may have a 3-track structure including 2-track power rails (for example, first and second backside power rails 72a and 72b) of a lower portion of the standard cell SCf and a 1-track signal line (for example, a backside signal line 72c) of the lower portion of the standard cell SCf. For example, the gate lines GT may include a gate line 73.

For example, the front wiring line 71a may extend in a first direction X at an upper portion of the first active region RX1 and may occupy a first track. The front wiring line 71a may be connected to a source/drain region 74a of the first active region RX1 through the via VA and the source/drain contact CA and may be connected to the front wiring layer M2 through the via V1. For example, the front wiring line 71b may extend in the first direction X at an upper portion of the second active region RX2 and may occupy a second track. The front wiring line 71b may be connected to a source/drain region of the second active region RX2 through the via VA and the source/drain contact CA and may be connected to the front wiring layer M2 through the via V1. As described above, the front wiring layer M2 may correspond to an output node of the standard cell SCf.

For example, the backside signal line 72c may extend in the first direction X at a lower portion of the standard cell SCf and may occupy one track. In some implementations, the backside signal line 72c may not overlap the front wiring lines 71a and 71b. The backside signal line 72c may be connected to the gate line 73 through the backside gate contact BCB and may transfer an input signal to the gate line 73. As described above, the backside signal line 72c may correspond to an input node of the standard cell SCf.

For example, the first backside power rail 72a may overlap a cell boundary BD and may be shared by another standard cell adjacent to the standard cell SCf in the second direction Y. For example, the second backside power rail 72b may overlap the cell boundary BD and may be shared by another standard cell adjacent to the standard cell SCf in the second direction Y. The first backside power rail 72a may provide a first supply voltage (for example, a power supply voltage) to a source/drain region through the backside via BVA, and the second backside power rail 72b may provide a second supply voltage (for example, a ground voltage) to the source/drain region through the backside via BVA.

FIGS. 22A to 22D illustrate a device in some implementations. For example, FIG. 22A illustrates a Fin field effect transistor (FinFET) 80a, FIG. 22B illustrates a gate-all-around field effect transistor (GAAFET) 80b, FIG. 22C illustrates a multi-bridge channel field effect transistor (MBCFET) 80c, and FIG. 22D illustrates a vertical field effect transistor (VFET) 80d. FIGS. 22A to 22C illustrate an example where one of two source/drain regions has been removed, and FIG. 22D illustrates a cross-sectional surface of the VFET 80d taken along a plane which is parallel to a plane consisting of a second direction Y and a vertical direction Z and passes through a channel CH of the VFET 50d.

Referring to FIG. 22A, a fin-type active pattern extending in a first direction X and a gate G extending in the second direction Y, between STIs, may constitute the FinFET 80a. A source/drain S/D may be formed at each of both sides of the gate G, and thus, a source and a drain may be apart from each other in the first direction X. An insulation layer may be formed between the channel CH and the gate G. In some implementations, the gate G and a plurality of active patterns, which are apart from one another in the second direction Y, may constitute the FinFET 80a.

Referring to FIG. 22B, active patterns (i.e., nanowires), which are apart from one another in a vertical direction Z and extend in a first direction X, and a gate G, which extends in a second direction Y, may constitute the GAAFET 80b. A source/drain S/D may be formed at each of both sides of the gate G, and thus, a source and a drain may be apart from each other in the first direction X. An insulation layer may be formed between the channel CH and the gate G. The number of nanowires included in the GAAFET 80b is not limited to the illustration of FIG. 22B.

Referring to FIG. 22C, active patterns (i.e., nanosheets), which are apart from one another in a vertical direction Z and extend in a first direction X and a gate G that extends in a second direction Y, may constitute the MBCFET 80c. A source/drain S/D may be formed at each of both sides of the gate G, and thus, a source and a drain may be apart from each other in the first direction X. An insulation layer may be formed between the channel CH and the gate G. The number of nanowires included in the MBCFET 80c is not limited to the illustration of FIG. 22C.

Referring to FIG. 22D, the VFET 80d may include a top source/drain T_S/D and a bottom source/drain B_S/D, which are apart from each other in a vertical direction Z with a channel CH therebetween. The VFET 80d may include a gate G, which surrounds a perimeter of the channel CH, between the top source/drain T_S/D and the bottom source/drain B_S/D. An insulation layer may be formed between the channel CH and the gate G.

However, the transistors in this disclosure are not limited to the structures described above. For example, an integrated circuit may include a ForkFET having a structure where an N-type transistor is relatively closer to a P-type transistor because nanosheets for a P-type transistor and nanosheets for an N-type transistor are separated from one another by a dielectric wall. Also, the integrated circuit may include a bipolar junction transistor as well as a FET such as a complementary FET (CFET), a negative capacitance FET (NCFET), or a carbon nanotube (CNT) FET.

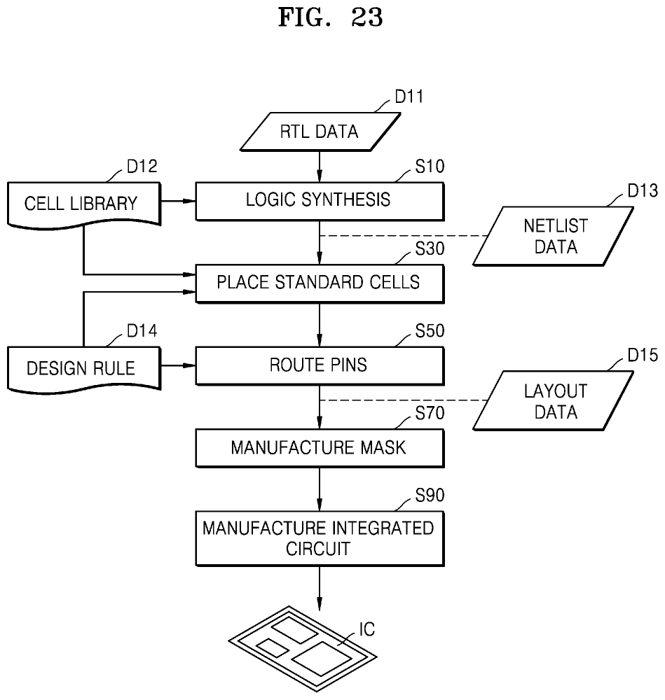

FIG. 23 is a flowchart illustrating a method of manufacturing an integrated circuit.

Referring to FIG. 23, the method of manufacturing an integrated circuit IC including standard cells and includes a plurality of operations S10, S30, S50, S70, and S90. A cell library (or a standard cell library) D12 may include information about standard cells, and for example, may include information about a function, a characteristic, a layout, etc. In some implementations, the cell library D12 may define a tap cell and a dummy cell as well as function cells, which generate an output signal from an input signal. In some implementations, the cell library D12 may define memory cells and dummy cells, which have the same footprint. A design rule D14 may include factors that a layout of the integrated circuit IC satisfies. For example, the design rule D14 may include factors such as a space between patterns, the minimum width of each pattern, and a routing direction of a wiring layer, in the same layer. In some implementations, the design rule D14 may define the minimum separation distance in the same track of a wiring layer.

In operation S10, a logic synthesis operation of generating netlist data D13 from register transfer level (RTL) data D11 may be performed. For example, a semiconductor design tool (for example, a logic synthesis tool) may perform logic synthesis with reference to the cell library D12 from the RTL data D11 written in hardware description language (HDL) such as very high speed integrated circuit (VHSIC) HDL (VHDL) and Verilog and may generate the netlist data D13 including a netlist or a bitstream. The netlist data D13 may correspond to an input of placement and routing described below.

In operation S30, standard cells may be placed. For example, the semiconductor design tool (for example, a P&R tool) may place standard cells used in the netlist data D13 with reference to the cell library D12. In some implementations, the semiconductor design tool may place a standard cell in a row extending in an X-axis direction or a Y-axis direction, and the placed standard cell may be supplied with power from a power rail extending along boundaries of the row.

In operation S50, pins of standard cells may be routed. For example, the semiconductor design tool may generate interconnections that electrically connect output pins and input pins of the placed standard cells with one another and may generate layout data D15, which defines the placed standard cells and the generated interconnections. The interconnection may include a via of a via layer and/or patterns of wiring layers. The wiring layers may include a front wiring layer which is disposed on a front side of a substrate and a backside wiring layer, which is disposed on a rear surface of the substrate. The layout data D15 may have, for example, a format such as GDSII and may include geometric information about the standard cells and the interconnections. The semiconductor design tool may refer to the design rule D14 while the pins of the standard cells are being routed. The layout data D15 may correspond to an output of placement and routing. Operation S50 or operations S30 and S50 may be referred to as a method of designing an integrated circuit.

In some implementations, as illustrated in FIGS. 1 to 7B and 18 to 21, the integrated circuit may include a backside wiring layer including backside power rails and at least one backside signal line. In detail, a standard cell may receive power such as a power supply voltage or a ground voltage through the backside power rails. Also, the standard cell may receive an input signal or may transfer an output signal through the at least one backside signal line. Accordingly, the performance of an integrated circuit may be enhanced, and the degree of routing freedom of a front wiring layer may be enhanced.

In some implementations, as illustrated in FIGS. 8 to 17, the integrated circuit may include a backside wiring layer and at least one backside contact, which are disposed at different levels and insulated from each other. In detail, a standard cell may receive power such as a power supply voltage or a ground voltage through the backside wiring layer. Also, the standard cell may receive an input signal or may transfer an output signal through the at least one backside contact. Accordingly, the performance of an integrated circuit may be enhanced, and the degree of routing freedom of a front wiring layer may be enhanced.

In operation S70, a process of manufacturing a mask may be performed. For example, optical proximity correction (OPC) for correcting distortion such as refraction caused by a characteristic of light in photolithography may be applied to the layout data D15. Based on data to which OPC is applied, patterns of a mask may be defined for forming patterns disposed in a plurality of layers, and at least one mask (or photomask) for forming the patterns of each of the plurality of layers may be manufactured. In some implementations, the layout of the integrated circuit IC may be restrictively modified in operation S70, and a process of restrictively modifying the integrated circuit IC in operation S70 may be a post-process for optimizing a structure of the integrated circuit IC and may be referred to as design polishing.

In operation S90, a process of manufacturing the integrated circuit IC may be performed. For example, a plurality of layers may be patterned by using the at least one mask that is manufactured in operation S70, and thus, the integrated circuit IC may be manufactured. Front-end-of-line (FEOL) may include, for example, an operation of planarizing and cleaning a wafer, an operation of forming a trench, an operation of forming a well, an operation of forming a gate line, and an operation of forming a source and a drain. Individual elements (for example, a transistor, a capacitor, and a resistor) may be formed on a substrate by the FEOL. Also, back-end-of-line (BEOL) may include, for example, an operation of performing silicidation of a gate region, a source region, and a drain region, an operation of adding a dielectric, a planarization operation, an operation of forming a hole, an operation of adding a metal layer, an operation of forming a via, and an operation of forming a passivation layer. The individual elements (for example, the transistor, the capacitor, and the resistor) may be connected to one another by the BEOL. In some implementations, middle-of-line (MOL) may be performed between the FEOL and the BEOL, and contacts may be formed on the individual elements. Subsequently, the integrated circuit IC may be packaged in a semiconductor package and may be used as a part of each of various applications.

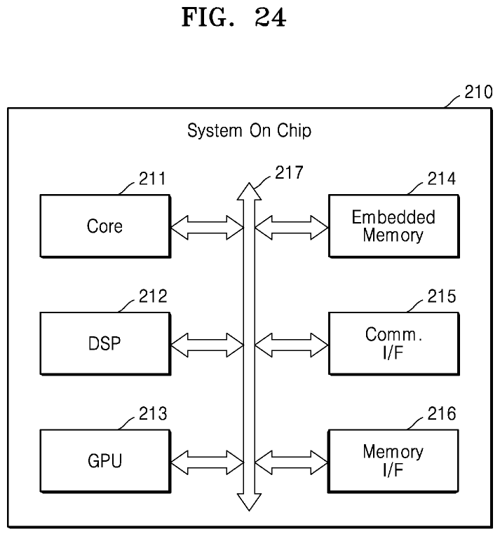

FIG. 24 is a block diagram illustrating a system-on-chip (SoC) 210.

Referring to FIG. 24, the SoC 210 may be referred to as an integrated circuit into which parts of a computing system or other electronic system are integrated. For example, in the SoC 210, an application processor (AP) may include a processor and parts for other functions. The SoC 210 may include a core 211, a digital signal processor (DSP) 212, a graphics processing unit (GPU) 213, an embedded memory 214, a communication interface 215, and a memory interface 216. The elements of the SoC 210 may communicate with one another through a bus 217.

The core 211 may process instructions and may control operations of the elements included in the SoC 210. For example, the core 211 may process a series of instructions, and thus, may drive an operating system and may execute applications of the operating system. The DSP 212 may process a digital signal (for example, a digital signal provided through the communication interface 215), and thus, may generate useful data. The GPU 213 may generate data for an image displayed through a display device from image data provided from the embedded memory 214 or the memory interface 216 and may encode the image data. In some implementations, an integrated circuit described above with reference to the drawings may be included in the core 211, the DSP 212, the GPU 213, and/or the embedded memory 214.

The embedded memory 214 may store data needed for operations of the core 211, the DSP 212, and the GPU 213. The communication interface 215 may provide an interface for one-to-one communication or a communication network. The memory interface 216 may provide an interface for an external memory of the SoC 210 (for example, dynamic random access memory (DRAM), flash memory, etc.).

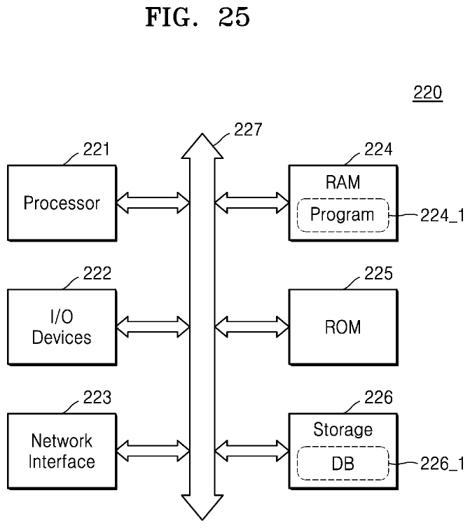

FIG. 25 is a block diagram illustrating a computing system 220 including a memory storing a program.

Referring to FIG. 25, the computing system 220 (or a computer) may perform a method of designing an integrated circuit in some implementations, and for example, may perform at least some of the operations of the flowchart described above. The computing system 220 includes a processor 221, input/output (I/O) devices 222, a network interface 223, random access memory (RAM) 224, read only memory (ROM) 225, and a storage device 226. The processor 221, the I/O devices 222, the network interface 223, the RAM 224, the ROM 225, and the storage device 226 may be connected with a bus 227 and may communicate with one another through the bus 227.

The processor 221 may be referred to as a processing unit, and for example, may include at least one core for executing an arbitrary instruction set (for example, Intel Architecture-32 (IA-32), 64-bit extension, IA-32, x86-64, PowerPC, Sparc, MIPS, ARM, IA-64, etc.) like a microprocessor, an AP, a DSP, and a GPU. For example, the processor 221 may access a memory (for example, the RAM 224 or the ROM 225) through the bus 227 and may execute instructions stored in the RAM 224 or the ROM 225.

In some implementations, the RAM 224 may store a program 224_1 for a method of designing an integrated circuit or at least a portion of the program 224_1, and the program 224_1 may allow the processor 221 to perform a method of designing an integrated circuit (for example, at least some of operations included in the methods of FIG. 23). That is, the program 224_1 may include a plurality of instructions executable by the processor 221, and the plurality of instructions included in the program 224_1 may allow the processor 221 to perform, for example, at least some of the operations included in the flowchart described above.

The storage device 226 may maintain data stored therein even when power supplied to the computing system 220 is cut off. In some implementations, the storage device 226 may store the program 224_1, and moreover, before the program 224_1 is executed by the processor 221, the program 224_1 or at least a portion thereof may be loaded from the storage device 226 into the RAM 224. Alternatively, the storage device 226 may store a file written in a program language, and the program 224_1 or at least a portion thereof, generated from the file by a compiler, may be loaded into the RAM 224. The storage device 226 may store a database (DB) 226_1, and the database 226_1 may include information needed for designing an integrated circuit (for example, information about designed blocks and/or the cell library D12 and/or the design rule D14 of FIG. 23).

The storage device 226 may store data which is to be processed by the processor 221 or data obtained through processing by the processor 221. That is, the processor 221 may process data stored in the storage device 226 to generate data, based on the program 224_1, and may store the generated data in the storage device 226. For example, the storage device 226 may store the RTL data D11, the netlist data D13, and/or the layout data D15 of FIG. 23.

The I/O devices 222 may include input devices such as a keyboard or a pointing device and may include output devices such as a display device or a printer. For example, a user may trigger execution of the program 224_1 by using the processor 221 through the I/O devices 222, may input the RTL data D11 and/or the netlist data D13 of FIG. 23, and may check the layout data D15 of FIG. 23. The network interface 223 may provide an access to a network outside the computing system 220. For example, the network may include a plurality of computing systems and communication links, and the communication links may include wired links, optical links, wireless links, or other arbitrary types of links.

Hereinabove, exemplary embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While the inventive concept has been particularly shown and described with reference to embodiments thereof, it will be understood that various changes in form and details may be made therein without departing from the spirit and scope of the following claims.

What is claimed is:

1. An integrated circuit comprising:
a standard cell including a first transistor and a second transistor, each of the first and second transistors disposed on a front side of a substrate;
a backside via passing through the substrate in a vertical direction with respect to the substrate;
a backside wiring layer including a backside power rail disposed on a backside of the substrate and connected with a first source/drain of the first transistor through the backside via; and
a backside contact extending in a first direction between the standard cell and the backside wiring layer and electrically connecting a second source/drain of the first transistor with a first source/drain of the second transistor,
wherein a height of a bottom level of the backside contact differs from a height of a top level of the backside power rail, and the backside contact is electrically insulated from the backside power rail.

2. The integrated circuit of claim 1, further comprising a front wiring layer disposed above the front side of the substrate, wherein the front wiring layer comprises:
a first front wiring line electrically connected with a gate of the first transistor; and
a second front wiring line electrically connected with a second source/drain of the second transistor,
wherein the first and second front wiring lines extend in the first direction and are arranged in one row in the first direction.

3. The integrated circuit of claim 2, wherein the front wiring layer further comprises:
a third front wiring line spaced apart from the first front wiring line or the second front wiring line in a second direction; and
a fourth front wiring line apart from the third front wiring line in the second direction,
wherein the second direction is perpendicular to the first direction.

4. The integrated circuit of claim 2, wherein the backside contact overlaps the first front wiring line at least partially along a vertical direction and overlaps the second front wiring line at least partially along the vertical direction.

5. The integrated circuit of claim 2, wherein the backside contact does not overlap the first front wiring line along a vertical direction and does not overlap the second front wiring line along the vertical direction.

6. The integrated circuit of claim 1, wherein the backside contact overlaps the backside power rail at least partially along a vertical direction.

7. The integrated circuit of claim 1, wherein the backside contact does not overlap the backside power rail along a vertical direction.

8. The integrated circuit of claim 1, wherein the backside contact comprises:
a first pattern connected to the second source/drain of the first transistor and extending in a second direction perpendicular to the first direction;
a second pattern connected to the first source/drain of the second transistor and extending in the second direction; and
a third pattern electrically connecting the first pattern to the second pattern and extending in the first direction.

9. An integrated circuit comprising:
a standard cell including a first transistor and a second transistor, each of the first and second transistors disposed on a front side of a substrate;
a backside via passing through the substrate in a vertical direction with respect to the substrate;
a backside wiring layer including a backside power rail disposed on a backside of the substrate and connected to a source of the first transistor through the backside via; and
a backside contact disposed between the standard cell and the backside wiring layer and electrically connected with a drain of the second transistor, the backside contact forming part of an output node,
wherein a height of a bottom level of the backside contact differs from a height of a top level of the backside power rail, and the backside contact is electrically insulated from the backside power rail.

10. The integrated circuit of claim 9, wherein the standard cell comprises:
a first active region extending in a first direction, and
a second active region disposed apart from the first active region in a second direction perpendicular to the first direction to extend in the first direction; and
the backside contact comprises:
a first pattern overlapping the first active region along a vertical direction and extending in the first direction, and
a second pattern contacting the first pattern and extending in the second direction.

11. The integrated circuit of claim 10, wherein the backside contact further comprises a third pattern contacting the second pattern, overlapping the second active region along the vertical direction, and extending in the first direction.

12. The integrated circuit of claim 10, wherein the first and second transistors are disposed in the first active region,
the standard cell further comprises a third transistor disposed in the second active region,
the first pattern is connected to the drain of the second transistor, and
the second pattern connects a drain of the third transistor to the drain of the second transistor.

13. The integrated circuit of claim 12, further comprising a front wiring layer disposed above the front side of the substrate, wherein the front wiring layer comprises:
a first front wiring line extending in the first direction at an upper portion of the first active region; and
a second front wiring line extending in the first direction at an upper portion of the second active region.

14. The integrated circuit of claim 13, wherein the front wiring layer further comprises a third front wiring line extending in the first direction from the first front wiring line and the second front wiring line.

15. The integrated circuit of claim 13, wherein the first front wiring line is connected to a gate of the second transistor.

16. An integrated circuit comprising:
a standard cell including a first transistor disposed on a front side of a substrate;
a backside via passing through the substrate in a vertical direction with respect to the substrate;
a backside wiring layer including a backside power rail disposed on a backside of the substrate and connected to a source of the first transistor through the backside via;
a first backside gate contact connected to a gate of the first transistor to pass through the substrate in the vertical direction; and
a first backside contact extending in a first direction between the standard cell and the backside wiring layer and connected to the gate of the first transistor through the first backside gate contact,
wherein a height of a bottom level of the first backside contact differs from a height of a top level of the backside power rail, and the first backside contact is electrically insulated from the backside power rail.

17. The integrated circuit of claim 16, wherein the standard cell further includes first and second active regions extending in the first direction and spaced apart from each other in a second direction perpendicular to the first direction, and
the first backside contact is disposed between the first and second active regions.

18. The integrated circuit of claim 16, wherein the standard cell further includes first and second active regions extending in the first direction and spaced apart from each other in a second direction perpendicular to the first direction, and
the first backside contact overlaps the first active region or the second active region at least partially along a vertical direction.

19. The integrated circuit of claim 16, wherein the standard cell further includes a second transistor, and the integrated circuit further comprises:
a second backside gate contact connected to a gate of the second transistor to pass through the substrate in the vertical direction; and
a second backside contact extending in the first direction between the standard cell and the backside wiring layer and connected to the gate of the second transistor through the second backside gate contact, and
the first and second backside contacts are arranged in one row in the first direction.

20. The integrated circuit of claim 16, wherein the standard cell further includes first and second active regions extending in the first direction and spaced apart from each other in a second direction perpendicular to the first direction,
wherein the integrated circuit further comprises a front wiring layer disposed above the front side of the substrate,
wherein the front wiring layer further comprises:
a first front wiring line extending in the first direction at an upper portion of the first active region;
a second front wiring line extending in the first direction at an upper portion of the second active region; and
a third front wiring line extending in the first direction from the first front wiring line and the second front wiring line.
